(19) United States
(12) Patent Application Publication
(10) Pub. No.: US 2023/0395512 A1
(43) Pub. Date: Dec. 7, 2023

(54) MEMORY DEVICE INCLUDING HIGH-ASPECT-RATIO CONDUCTIVE CONTACTS

(71) Applicant: Micron Technology, Inc., Boise, ID (US)

(72) Inventors: Shuangqiang Luo, Boise, ID (US); Indra V. Chary, Boise, ID (US)

(21) Appl. No.: 17/848,021

(22) Filed: Jun. 23, 2022

Related U.S. Application Data
(60) Provisional application No. 63/347,853, filed on Jun. 1, 2022.

(51) Int. Cl. H01L 23/535; H01L 23/528; H01L 27/11556; H01L 27/11582

(52) U.S. Cl. CPC H01L 23/535; H01L 23/5283; H01L 27/11556; H01L 27/11582

(57) ABSTRACT

Some embodiments include apparatuses and methods of forming the apparatuses. One of the apparatuses includes memory cells located on tiers; control gates for the memory cells and located on respective tiers; a dielectric structure over the control gates; a first conductive contact formed in the dielectric structure and contacting a first control gate, the first conductive contact having a first length; and a second conductive contact formed in the dielectric structure and contacting the second control gate, the second conductive contact having a second length unequal to the first length, wherein the second conductive contact includes a first portion and a second portion, the second portion is between the first portion and the second control gate, the first portion including a first region having a first width, the second portion including a second region having a second width, and the second width being greater than the first width.

### PRIORITY APPLICATION

This application claims the benefit of priority to U.S. Provisional Application Ser. No. 63/347,853, filed Jun. 1, 2022, which is incorporated herein by reference in its entirety.

### FIELD

Embodiments described herein relate to memory devices including vertical conductive contacts. Some embodiments relate to vertical conductive contacts at staircase structures of the memory device.

### BACKGROUND

Some conventional memory devices have vertical conductive structures as part of conductive paths that provide electrical signals between elements of the memory device. For example, some memory devices have vertical conductive structures to form contacts with respective control gates (e.g., word line structures) for memory cells of the memory device. Signals can be provided to the control gates through the vertical conductive structures. In conventional memory devices, such vertical conductive structures have a relatively high aspect ratio. At a certain dimension of the memory device, forming such high-aspect-ratio vertical conductive structures may impact (e.g., degrade or damage) other vertical conductive structures or other structures in the memory device. Such an impact can lead to an unreliable or defective device.

### BRIEF DESCRIPTION OF THE DRAWINGS

FIG. 1 shows an apparatus in the form of a memory device, according to some embodiments described herein.

FIG. 2 shows a schematic of a memory device having a memory array and memory cell blocks, according to some embodiments described herein.

FIG. 3A shows a top view of a structure of the memory device of FIG. 2 including the memory array, staircase regions, and dielectric structures between respective blocks of the memory device, according to some embodiments described herein.

FIG. 3B shows detail of a portion of the memory device of FIG. 3A, according to some embodiments described herein.

FIG. 3C shows a portion (e.g., a side view) of the memory device of FIG. 3B, according to some embodiments described herein.

FIG. 3D and FIG. 3E show details (e.g., side view and top view, respectively) of a conductive contact (e.g., word line contact) of the memory device of FIG. 3C, according to some embodiments described herein.

FIG. 3F and FIG. 3G show details (e.g., side view and top view, respectively) of another conductive contact (e.g., word line contact) of the memory device of FIG. 3C, according to some embodiments described herein.

FIG. 4 through FIG. 15 show different views of structures during processes of forming the memory device of FIG. 2 through FIG. 3E, according to some embodiments described herein.

### DETAILED DESCRIPTION

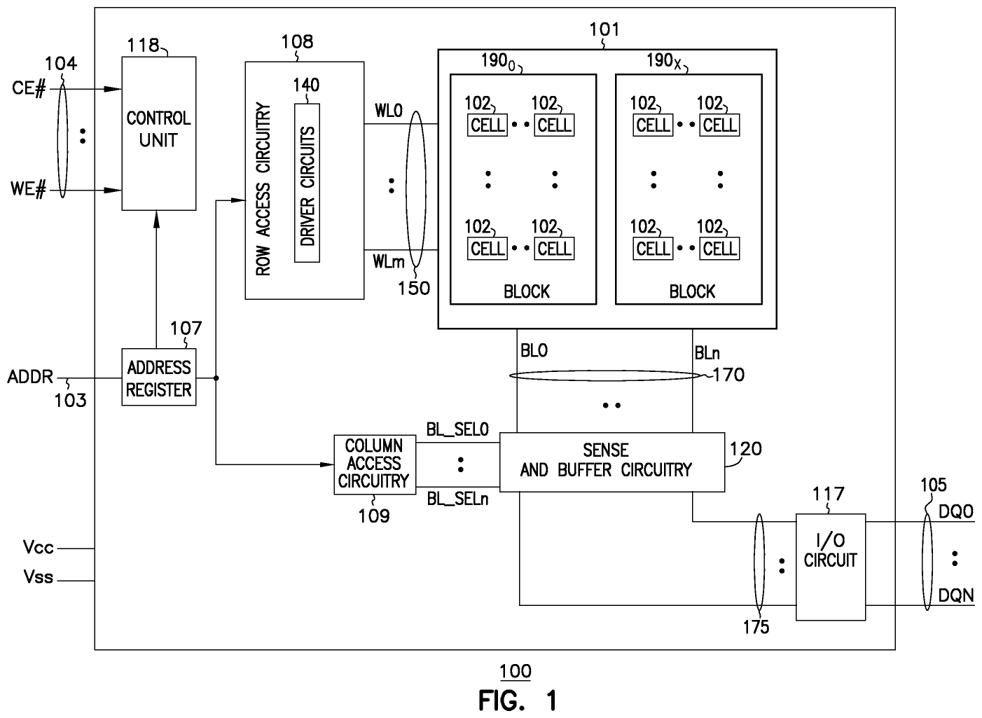

The techniques described herein involve vertical conductive contacts in memory a device including relatively high-aspect-ratio conductive contacts. The conductive contacts described herein are part of conductive paths coupled to control gates (e.g., word lines) for memory cells of the memory device. As described above, forming high-aspect-ratio vertical conductive structures in some conventional memory devices that have a certain dimension may impact other structures of the memory device. The techniques described herein include improved processes to form conductive contacts including high-aspect-ratio conductive contacts for the control gates. The conductive contacts may be formed at a staircase structure of the memory device. In an example, the techniques described herein include processes that use a combination of a dielectric structure and dielectric liner, among other elements, during formation of the conductive contacts. The described processes can result in improved conductive contacts and mitigate impact and limitation that conventional techniques may face. Other improvements and benefits of the described techniques are further discussed below with reference to FIG. 1 through FIG. 15.

FIG. 1 shows an apparatus in the form of a memory device 100, according to some embodiments described herein. Memory device 100 can include a memory array (or multiple memory arrays) 101 containing memory cells 102 arranged in blocks (blocks of memory cells), such as blocks 190₀ through 190ₓ (e.g., there are X+1 blocks in memory device 100). In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines 150 and data lines 170. Access lines 150 can include word lines, which can include global word lines and local word lines (e.g., control gates). Data lines 170 can include bit lines (e.g., local bit lines). Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks 190₀ through 190ₓ and data lines 170 to selectively exchange information (e.g., data) with memory cells 102.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which blocks 190₀ through 190ₓ are to be accessed during a memory operation. Memory device 100 can include drivers (driver circuits) 140, which can be part of row access circuitry 108. Drivers 140 can operate (e.g., operate as switches) to form (or not to form) conductive paths (e.g., current paths) between nodes (e.g., global access lines) providing voltages and respective access lines 150 during operations of memory device 100.

Memory device 100 can perform a read operation to read (e.g., sense) information (e.g., previously stored information) from memory cells 102 of blocks 190₀ through 190ₓ, or a write (e.g., programming) operation to store (e.g., program) information in memory cells 102 of blocks 190₀ through 190ₓ. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks 190₀ through 190ₓ.

Memory device 100 can include a control unit 118 that can be configured to control memory operations of memory device 100 based on control signals on lines 104. Examples of the control signals on lines 104 include one or more clock signals and other signals (e.g., a chip-enable signal CE #, a write-enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that may cause memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks 190₀ through 190ₓ and provide the value of the information to lines 175, which can include global data lines (e.g., global bit lines). Sense and buffer circuitry 120 can also be configured to use signals on lines 175 to determine the value of information to be stored (e.g., programmed) in memory cells 102 of blocks 190 and 191 (e.g., during a write operation) based on the values (e.g., voltage values) of signals on lines 175 (e.g., during a write operation).

Memory device 100 can include input/output (I/O) circuitry 117 to exchange information between memory cells 102 of blocks 190₀ through 190ₓ and lines (e.g., I/O lines) 105. Signals DQO through DQN on lines 105 can represent information read from or stored in memory cells 102 of blocks 190₀ through 190ₓ. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits. A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3-dimensional (3-D) NAND) or a NOR flash memory device, or another kind of memory device, such as a variable resistance memory device (e.g., a phase change memory device or a resistive Random-Access Memory (RAM) device.

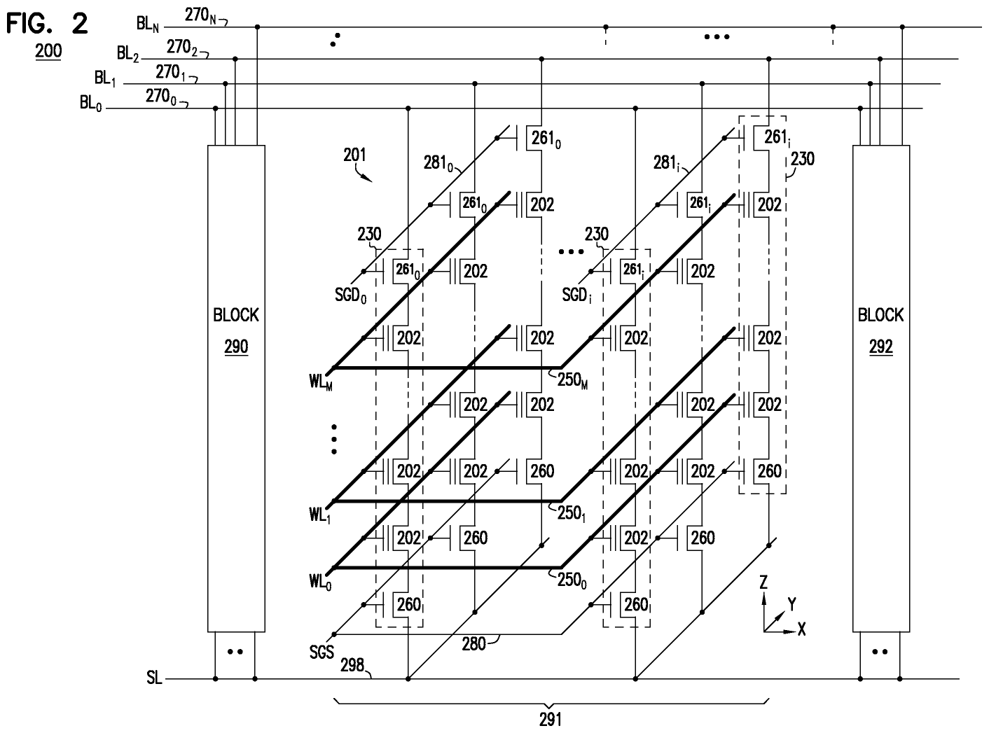

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 15.

FIG. 2 shows a schematic of a memory device 200 having a memory array 201, and blocks (e.g., memory cell blocks) 290, 291, and 292, according to some embodiments described herein. For simplicity, only detail for elements of block 291 is shown in FIG. 2. Blocks 290 and 292 have similar elements as block 291.

Memory device 200 can include a non-volatile (e.g., NAND flash memory device) or other types of memory devices. Memory device 200 can correspond to memory device 100. For example, memory array (or multiple memory arrays) 201 and blocks 290, 291, and 292 can correspond to memory array 101 and three of blocks 190₀ through 190ₓ, respectively, of memory device 100 of FIG. 1.

As shown in FIG. 2, memory device 200 can include memory cells 202, data lines 270₀ through 270_{N} (270₀-270_{N}), and control gates 250₀ through 250_{M} in block 291. Data lines 270₀-270_{N} can correspond to part of data lines 170 of memory device 100 of FIG. 1. In FIG. 2, label “N” (index N) next to a number (e.g., 270_{N}) represents the number of data lines of memory device 200. For example, if memory device 200 includes 16 data lines, then N is 15 (data lines 270₀ through 270₁₅). In FIG. 2, label “M” (index M) next to a number (e.g., 250_{M}) represents the number of control gates of memory device 200. For example, if memory device 200 includes 128 control gates, then M is 127 (control gates 250₀ through 250₁₂₇). Memory device 200 can have the same number of control gates (e.g., M−1 control gates) among the blocks (e.g., blocks 290, 291, and 292) of memory device 200.

In FIG. 2, data lines 270₀-270_{N} can include (or can be part of) bit lines (e.g., local bit lines) of memory device 200. As shown in FIG. 2, data lines 270₀-270_{N} can carry signals (e.g., bit line signals) BL₀ through BL_{N}, respectively. In the physical structure of memory device 200, data lines 270₀-270_{N} can be structured as conductive lines and have respective lengths extending in the Y-direction (e.g., a direction from one memory block to another).

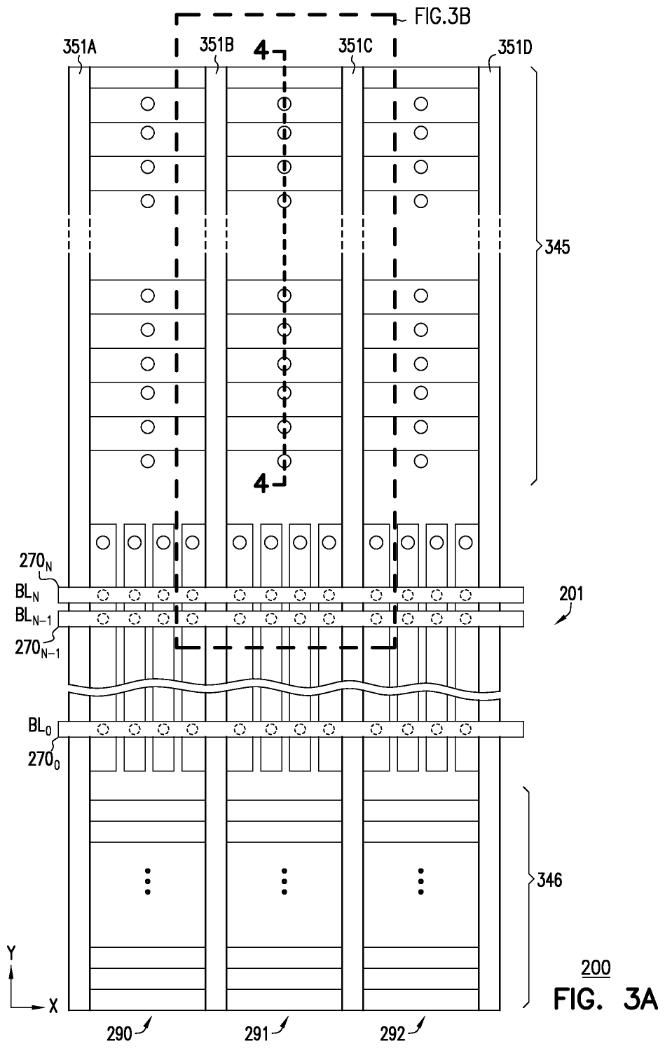

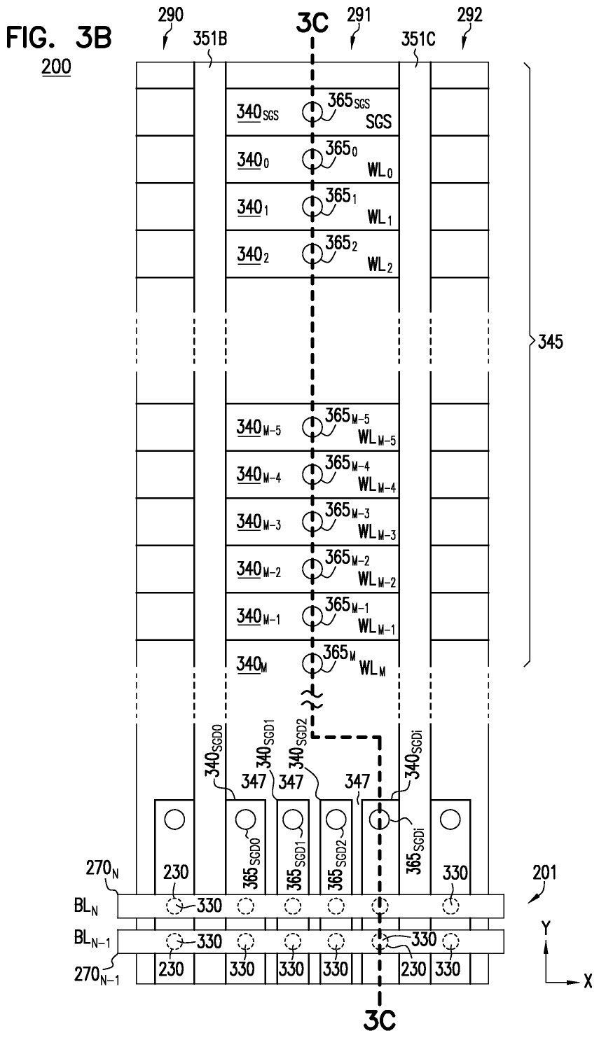

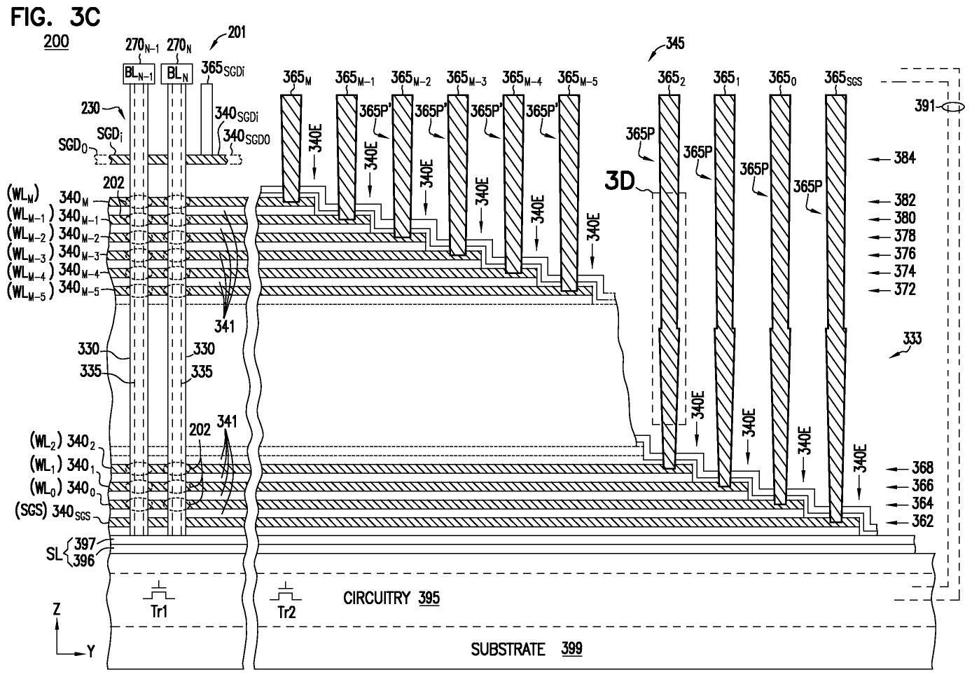

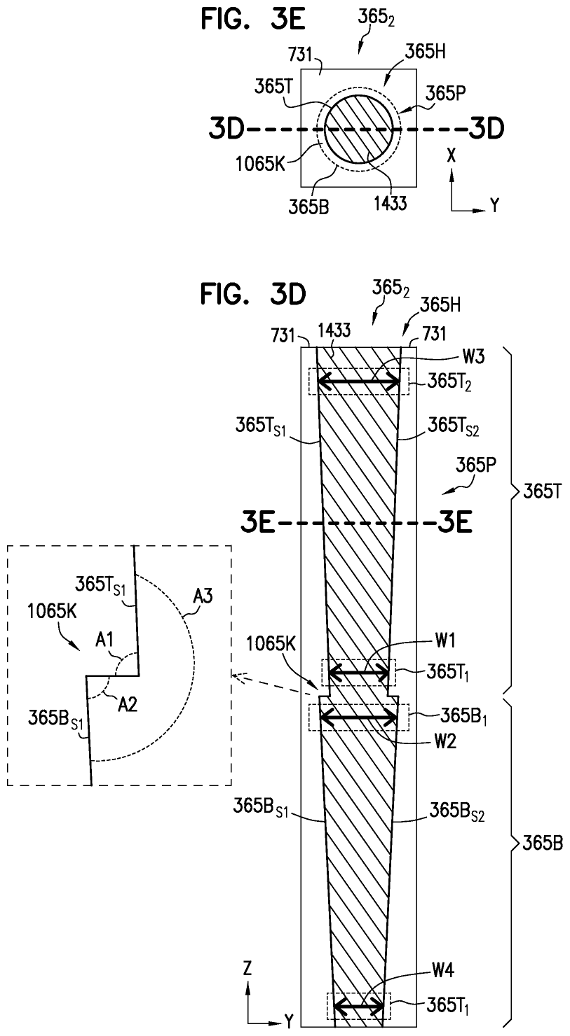

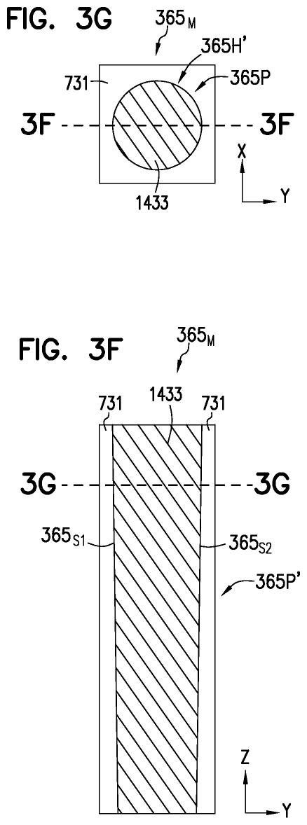

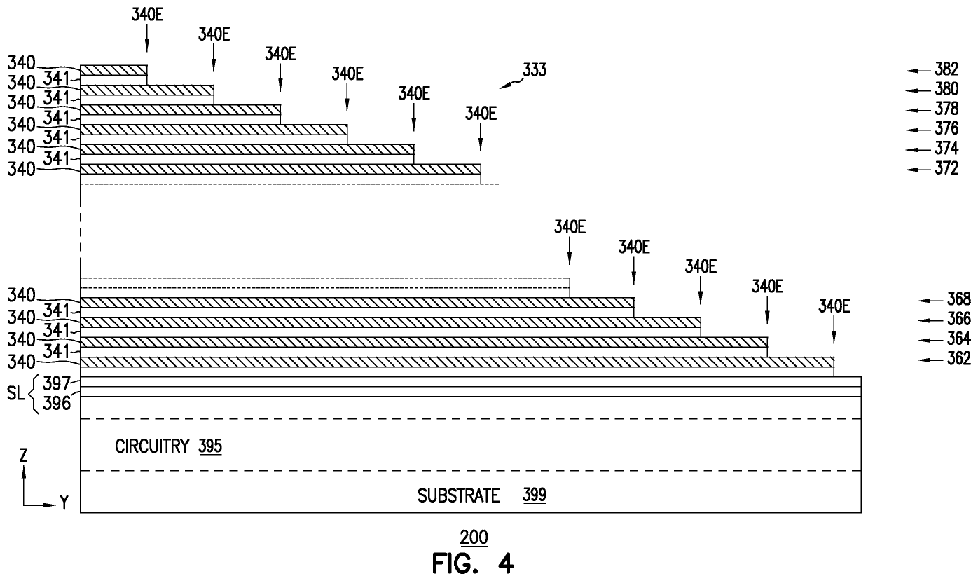

FIG. 2 shows directions X, Y, and Z that can be relative to the physical directions (e.g., dimensions) of the structure of memory device 200. For example, the Z-direction can be a direction perpendicular to (e.g., vertical direction with respect to) a substrate of memory device 200 (e.g., a substrate 399 shown in FIG. 3C). The Z-direction is perpendicular to the X-direction and Y-direction (e.g., the Z-direction is perpendicular to an X-Y plane of memory device 200).

As shown in FIG. 2, memory cells 202 can be organized into separate blocks (memory blocks or blocks of memory cells) such as blocks 290, 291, and 292. FIG. 2 shows memory device 200 including three blocks 290, 291, and 292 as an example. However, memory device 200 can include numerous blocks. The blocks (e.g., blocks 290, 291, and 292) of memory device 200 can share data lines (e.g., data lines 270₀-270_{N}) to carry information (in the form of signals) read from or to be stored in memory cells of selected memory cells (e.g., selected memory cells in block 290, 291, or 292) of memory device 200.

Control gates 250₀-250_{M} in block 291 can be part of access lines (e.g., word lines). The access lines (that include control gates 250₀-250_{M}) of memory device 200 can correspond to access lines 150 of memory device 100 of FIG. 1.

Other blocks (e.g., blocks 290 and 292) of memory device 200 can have control gates similar to (or the same as) control gates 250₀-250_{M} of block 291. Blocks 290, 291, and 292 can be accessed separately (e.g., accessed one block at a time). For example, block 291 can be accessed at one time using control gates 250₀-250_{M}, and block 290 or 291 can be accessed at another time using control gates in the respective block.

In the physical structure of memory device 200, control gates 250₀-250_{M} can be formed on different levels (e.g., layers) of memory device 200 in the Z-direction. In this example, the levels (e.g., layers) of control gates 250₀-250_{M} can be formed (e.g., stacked) one level (one layer of material) over another (another layer of material) in the Z-direction.

As shown in FIG. 2, memory cells 202 can be included in respective memory cell strings 230. For simplicity, only three memory cell strings 230 are labeled in FIG. 2. Each of memory cell strings 230 can have series-connected memory cells (e.g., M+1 (e.g., 128) series-connected memory cells) in the Z-direction. In a physical structure of memory device 200, memory cells 202 in each of memory cell strings 230 can be formed (e.g., stacked vertically one over another) in different levels (physical portions) of memory device 200. The levels of memory device 200 can be included in (or can correspond to) respective tiers (stacked one over another in the Z-direction) of memory device 200. In the example of FIG. 2, memory device 200 can include M+1 tiers (e.g., 128 tiers, where M=127) of memory cells and respective control gates. The number of memory cells 202 in each of memory cell strings 230 can be equal to the number of levels (e.g., the number of tiers). Thus, in the example of FIG. 2, there can be 128 levels (layers) of memory cells 202 in the Z-direction.

The number of memory cells 202 in each of memory cell strings 230 can also be equal to the number of levels (e.g., the number of tiers) of control gates (e.g., control gates 250₀-250_{M}) of memory device 200. For example, if each memory cell string 230 has 128 (e.g., M=127) memory cells 202, then there are 128 corresponding levels (e.g., 128 tiers) of control gates 250₀-250_{M} for the 128 memory cells.

As shown in FIG. 2, control gates 250₀-250_{M} can carry corresponding signals WL₀-WL_{M}. As mentioned above, control gates 250₀-250_{M} can include (or can be parts of) access lines (e.g., word lines) of memory device 200. Each of control gates 250₀-250_{M} can be part of a structure (e.g., a level) of a conductive material (e.g., a layer of conductive material) located in a level of memory device 200. Memory device 200 can use signals WL₀-WL_{M} to selectively control access to memory cells 202 of block 291 during an operation (e.g., read, write, or erase operation). For example, during a read operation, memory device 200 can use signals WL₀-WL_{M} to control access to memory cells 202 of block 291 to read (e.g., sense) information (e.g., previously stored information) from memory cells 202 of block 291. In another example, during a write operation, memory device 200 can use signals WL₀-WL_{M} to control access to memory cells 202 of block 291 to store information in memory cells 202 of block 291.

As shown in FIG. 2, memory cells in different memory cell strings in block 291 can share (e.g., can be controlled by) the same control gate in block 291. For example, memory cells 202 (of different memory cell strings 230) coupled to control gate 250₀ can share (can be controlled by) control gate 250₀. In another example, memory cells 202 (of different memory cell strings 230) coupled to control gate 250₁ can share (can be controlled by) control gate 250₁.

Memory device 200 can include a source (e.g., a source line, a source plate, or a source region) 298 that can carry a signal (e.g., a source line signal) SL. Source 298 can include (e.g., can be formed from) a conductive structure (e.g., conductive region) of memory device 200. The conductive structure of source 298 can include multiple levels (e.g., layers) of conductive materials stacked one over another over a substrate of memory device 200. Source 298 can be a common conductive structure (e.g., common source plate or common source region) of block 290, 291, and 292. Source 298 can be coupled to a ground connection (e.g., ground plate) of memory device 200. Alternatively, source 298 can be coupled to a connection (e.g., a conductive region) that is different from a ground connection.

As shown in FIG. 2, memory device 200 can include select transistors (e.g., drain select transistors) 261₀ through 261ᵢ (261₀-261ᵢ) and select gates (e.g., drain select gates) 281₀ through 281ᵢ in block 291. Transistors 261₀ can share the same select gate 281₀. Transistors 261ᵢ can share the same select gate 281ᵢ. Select gates 281₀-281ᵢ can carry signals SGD₀ through SGDᵢ (SGD₀-SGDᵢ), respectively.

Transistors 261₀-261ᵢ can be controlled (e.g., turned on or turned off) by signals SGD₀-SGDᵢ, respectively. During a memory operation (e.g., a read or write operation) of memory device 200, transistors 261₀ and transistors 261ᵢ can be turned on one group at a time (e.g., either the group of transistors 261₀ or the group of transistors 261ᵢ can be turned on at a particular time). Transistors 261₀ can be turned on (e.g., by activating signal SGD₀) to couple memory cell strings 230 of block 291 to respective data lines 270₀-270_{N}. Transistors 261ᵢ can be turned on (e.g., by activating signal SGDᵢ) to couple memory cell strings 230 of block 291 to respective data lines 270₀-270_{N}. Transistors 261₀-261ᵢ can be turned off (e.g., by deactivating signals SGD0-SGDi) to decouple the memory cell strings 230 of block 291 from respective data lines 270₀-270_{N}.

Memory device 200 can include transistors (e.g., source select transistors) 260 in block 291, each of which can be coupled between source 298 and memory cells 202 in a respective memory cell string (one of memory cell strings 230) of block 291. Memory device 200 can include a select gate (e.g., source select gate) 280 that can be shared by transistors 260. Transistors 260 can be controlled (e.g., turned on or turned off) by the same signal, such as SGS signal (e.g., source select gate signal) provided on select gate 280. During a memory operation (e.g., a read or write operation) of memory device 200, transistors 260 can be turned on (e.g., by activating an SGS signal) to couple memory cell strings 230 to source 298. Transistors 260 can be turned off (e.g., by deactivating the SGS signal) to decouple memory cell strings 230 from source 298.

Memory device 200 includes other components, which are not shown in FIG. 2 so as not to obscure the example embodiments described herein. Some of the structures of memory device 200 are described below with reference to FIG. 3A through FIG. 15. For simplicity, detailed description of the same element among the drawings (FIG. 1 through FIG. 15) is not repeated.

FIG. 3A shows a top view of a structure of memory device 200 including a memory array (memory cell array) 201, staircase regions 345 and 346, and dielectric structures (e.g., block dividers) 351A, 351B, 351C, and 351D between respective blocks 290, 291, and 292, according to some embodiments described herein.

In the figures (drawings) herein, similar or the same elements of memory device 200 of FIG. 2 and other figures (e.g., FIG. 3A through FIG. 15) are given the same labels. Detailed descriptions of similar or the same elements may not be repeated from one figure to another figure. For simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements shown in the drawings described herein are not scaled.

As shown in FIG. 3A, blocks (blocks of memory cells) 290, 291, and 292 of memory device 200 can be located side-by-side from one block to another in the X-direction. Three blocks 290, 291, and 292 are shown as an example. Memory device 200 can include numerous blocks. Block 291 of FIG. 3A is schematically shown and described above with reference to FIG. 2.

In FIG. 3A, dielectric structures 351A, 351B, 351C, and 351D can be formed to divide (e.g., organize) memory device 200 into physical blocks (e.g., blocks 290, 291, and 292). Dielectric structures 351A, 351B, 351C, and 351D can have lengths extending in the Y-direction. Each of dielectric structures 351A, 351B, 351C, and 351D can include (or can be formed in) a slit (not labeled) between two adjacent blocks. The slit can have sidewalls (e.g., edges) opposing each other in the X-direction and adjacent two respective blocks. The slit can include (or can be) a trench having a depth in the Z-direction. For example, dielectric structure 351B can be formed (e.g., located) in a slit between blocks 290 and 291, in which the slit can have opposing sidewalls (e.g., edges) adjacent respective blocks 290 and 291. Dielectric structure 351C can be formed in a slit between blocks 291 and 292, in which the slit can have opposing sidewalls adjacent respective blocks 291 and 292. Other dielectric structures 351A and 351D can be located adjacent respective blocks shown in FIG. 3A.

Each of dielectric structures 351A, 351B, 351C, and 351D can include a dielectric material (or dielectric materials) formed in (e.g., filling) a respective slit. Dielectric structures 351A, 351B, 351C, and 351D can separate (e.g., physically and electrically separate) one block from another. For example, as shown in FIG. 3A, dielectric structure 351B can separate block 291 from block 290. Dielectric structure 351C can separate block 291 from block 292.

As shown in FIG. 3A, data lines 270₀ through 270_{N} (associated with signals BL₀ through BL_{N}) of memory device 200 can be located over blocks 290, 291, and 292 (with respect to the Z-direction). Data lines 270₀ through 270_{N} can have respective lengths extending in the X-direction. Data lines 270₀ through 270_{N} can extend over (e.g., on top of) and across (in the X-direction) blocks 290, 291, and 292 and can be shared by blocks 290, 291, and 292.

Staircase regions 345 and 346 of memory device 200 can be located on respective sides (in the Y-direction) of memory array 201. Staircase regions 345 and 346 are part of memory device 200 where conductive contacts (labeled in FIG. 3B, e.g., conductive contacts 365_{SGS}, 365₀ through 365_{M}, and 365_{SGD0} through 365_{SGDi}) can be formed to provide electrical connections (e.g., signals) to respective select gates and control gates (e.g., shown in FIG. 2 as select gates 280, 281₀ and 281₁ and control gates 250₀ through 250_{M}) in respective blocks 290, 291, and 292 of memory device 200. Staircase regions 345 and 346 can also include other structures that are not shown in FIG. 3A.

In FIG. 3A, staircase regions 345 and 346 can include similar structures. However, for simplicity, details of staircase region 346 are omitted from the description herein. In an alternative structure of memory device 200, staircase region 346 can be omitted from memory device 200, such that only staircase region 345 (and not both staircase regions 345 and 346) is included in memory device 200. A portion labeled “FIG. 3B” in FIG. 3A is shown in detail in FIG. 3B. Line 4-4 in FIG. 3A shows a location of a portion (e.g., a side view (e.g., a cross-section)) of memory device 200 during processes of forming part of memory device 200 as described below with reference to FIG. 4 through FIG. 15.

As shown in FIG. 3B, memory device 200 can include pillars 330 (shown in top view) in each of block 290, 291, and 292. Pillars 330 are memory cell pillars. The structure of pillars 330 is different from the structure of the pillars of conductive contacts (e.g., conductive contacts 365_{SGS}, 365₀ through 365_{M} and 365_{SGD0} through 365_{SGDi}) of memory device 200. Each pillar 330 is part of a respective memory cell string 230 (also schematically shown in FIG. 2). Conductive contacts 365₀ through 365_{M} can be called word line contacts (or local word line contacts). For simplicity, only some of the conductive contacts 365₀ through 365_{M} of memory device 200 are shown in FIG. 3B (and other figures described herein) including conductive contacts 365₀, 365₁, 365₂, 365_{M-5}, 365_{M-4}, 365_{M-3}, 365_{M-2}, 365_{M-1}, and 365_{M}.

As shown in FIG. 3B, pillars (memory cell pillars) 330 can be located under (below) and coupled to respective data lines (only data lines 270_{N-1} and 270_{N} are shown). Memory cells 202 of a memory cell string can be located (e.g., can be formed vertically) long the length (shown in FIG. 3C) of a corresponding pillar 330. Pillars 330 (and associated memory cell strings) of blocks 290, 291, and 292 can share data lines 270₀ through 270_{N}.

As shown in FIG. 3A and FIG. 3B, data lines 270₀ through 270_{N} (associated with signals BL₀ through BL_{N}) of memory device 200 can be located over (above) pillars 330 (and over associated memory cell strings) in memory array 201. Data lines 270₀ through 270_{N} can be coupled to respective pillars 330 (which are located under data lines 270₀ through 270_{N} in the Z-direction).

As shown in FIG. 3B, conductive contacts 365₀ through 365_{M} can be located (e.g., can be formed) in a row in which each row can include many conductive contacts in the Y-direction. FIG. 3B, shows conductive contacts 365₀ through 365_{M} being aligned (e.g., in a straight line from a top view) in the Y-direction as an example. However, conductive contacts 365₀ through 365_{M} may not be aligned in a row (e.g., they may be staggered). FIG. 3B shows block 291 including one row of conductive contacts as an example. However, block 291 (and other blocks) of memory device 200 can include a different number of rows of conductive contacts.

As shown in FIG. 3B (e.g., viewing from a direction perpendicular to the X-Y plane (e.g., top view)), conductive contacts 365_{SGS}, 365₀-365_{M}, and 365_{SGD0}-365_{SGDi} can have a circular shape. For example, the boundary of a cross-section of each conductive contact (e.g., conductive contact 365_{M}) has a circular boundary when viewed from a direction perpendicular to the X-Y plane.

As shown in FIG. 3B, memory device 200 can include conductive materials 340_{SGS}, 340₀ through 340_{M}, and 340_{SGD0} through 340_{SGDi} (340_{SGD0}-340_{SGD1}) in block 291 that can form (e.g., can be materials included in) respective select gate (e.g., source select gate) 280, control gates 250₀ through 250_{M}, and select gates (e.g., drain select gates) 280₀ and 280ᵢ (FIG. 2). For simplicity, only conductive materials 340₀, 340₁, 340₂, 340_{M-5}, 340_{M-4}, 340_{M-3}, 340_{M-2}, 340_{M-1}, and 340_{M} among conductive materials 340₀ through 340_{M} (340₀-340_{M}) are shown in FIG. 3B and other figures described herein. For example, other conductive materials between conductive materials 340₂ and 340_{M-5} are not shown in FIG. 3B (and FIG. 3C).

In FIG. 3B, conductive materials (e.g., four separate conductive materials) 340_{SGD0}, 340_{SGD1}, 340_{SGD2}, and 340_{SGDi} can form four respective drain select gates of block 291. The drain select gates formed by conductive materials 340_{SGD1} and 340_{SGD2} in FIG. 3B are not shown in FIG. 2. As shown in FIG. 3B, conductive materials 340_{SGD0}-340_{SGDi} (FIG. 3B) can be electrically separated from each other by a gap 347 (which can be filled with a dielectric material (or materials)). For simplicity, FIG. 3B does not give labels for other conductive materials that form respective select gates and control gates of blocks 290 and 292.

The four conductive materials 340_{SGD0}, 340_{SGD1} and 340_{SGD2} and 340_{SGDi} included in four respective drain select gates on the same level in block 291 can be associated with four respective sub-blocks of block 291. FIG. 3B shows an example of memory device 200 including four drain select gates in each block (e.g., block 291) formed by four corresponding conductive materials 340_{SGD0}, 340_{SGD1}, 340_{SGD2}, and 340_{SGDi} on the same level (e.g., level 372 in FIG. 3C). However, the number of drain select gates on the same level in a block of memory device 200 can be different from four. For example, the number of drain select gates on the same level in a block can be based on (e.g., equal to) the number of sub-blocks in a block.

Line 3C-3C in FIG. 3B shows a location of a portion (e.g., a side view (e.g., a cross-section)) of memory device 200 shown in FIG. 3C.

As shown in FIG. 3C, memory device 200 can include levels 362, 364, 366, 368, 372, 374, 376, 378, 380, 382, and 384 that are physical layers (e.g., portions) in the Z-direction of memory device 200. Conductive materials 340_{SGS}, 340₀-340_{M}, and 340_{SGD0}-340_{SGDi} can be located (e.g., stacked) one level (e.g., one layer) over another in respective levels 362, 364, 366, 368, 372, 374, 376, 378, 380, 382, and 384 in the Z-direction. Conductive materials 340_{SGS}, 340₀-340_{M}, and 340_{SGD0}-340_{SGDi} can also be called levels of conductive materials 340_{SGS}, 340₀-340_{M}, and 340_{SGD0}-340_{SGDi}. As shown in FIG. 3C, conductive materials 340_{SGD0}-340_{SGDi} can be located on the same level (e.g., level 384).

As shown in FIG. 3C, conductive materials 340_{SGS}, 340₀-340_{M}, and 340_{SGDi} can interleave with dielectric materials 341 in the Z-direction. Dielectric materials 341 can include silicon dioxide. Conductive materials 340_{SGS}, 340₀-340_{M}, and 340_{SGDi} can include metal (e.g., tungsten, tungsten-based material, or other metal), other conductive materials, or a combination of conductive materials. Dielectric materials 341 are formed for electrically separating (in the Z-direction) respective control gates (e.g., control gates associated signals WL₀-WL_{M}) from each other. Dielectric materials 341 are also formed for electrically separating (in the Z-direction) other elements (e.g., source select gate and drain select gate) of memory device 200 from adjacent control gates.

Signals SGS, WL₀ through WL_{M}, SGD₀, and SGDᵢ in FIG. 3C associated with respective conductive materials in FIG. 3C are the same signals shown in FIG. 2. Conductive material 340_{SGS} can form select gate 280 (associated with signal SGS) of FIG. 2. Conductive materials 340₀-340_{M} can form control gates 250₀ through 250_{M} (associated with signals WL₀ through WL_{M}, respectively) of FIG. 2. Conductive material 340_{SDG0} and 340_{SGDi} (associated with signals SGD₀, and SGDᵢ) can form select gates 281₀ and 281ᵢ, respectively, of FIG. 2.

FIG. 3C shows an example of memory device 200 including one level of conductive materials 340_{SGS} that forms a select gate (e.g., source select gate associated with signal SGS). However, memory device 200 can include multiple levels (similar to level 362) of conductive materials (e.g., multiple levels of conductive material 340_{SGS}) located under (in the Z-direction) the level of conductive materials 340₀ (e.g., below level 364) to form multiple source select gates of memory device 200.

FIG. 3C shows an example of memory device 200 including one level (e.g., level 384) of multiple drain select gates (on the same level, formed by respective conductive materials 340_{SGD0}-340_{SGDi}). However, memory device 200 can include multiple levels (similar to level 384) in which each of such multiple levels can include multiple drain select gates (e.g., four drain select gates in each of the multiple levels).

As shown in FIG. 3C, memory device 200 can include a staircase structure 333 located in staircase region 345 (FIG. 3B also shows a top view of staircase region 345). For simplicity, only a portion of staircase structure 333 is shown in FIG. 3C (e.g., a middle portion of staircase structure 333 is omitted from FIG. 3C). As shown in FIG. 3C, respective portions (e.g., end portions) of conductive materials 340_{SGS} and 340₀-340_{M} and their respective edges (e.g., steps (or risers)) 340E can collectively form staircase structure 333. As shown in FIG. 3C, dielectric materials 341 can also include edges adjacent (e.g., aligned in the Z-direction with) respective edges 340E. Thus, staircase structure 333 can also be formed in part by portions and edges (e.g., edges that are aligned with edges 340E) of dielectric materials 341.

FIG. 3C also shows tiers of memory device 200 on respective levels (e.g., levels 362, 364, 366, 368, 372, 374, 376, 378, 380, 382, and 384) of memory device 200. A tier of memory device 200 can include a level of conductive material (e.g., conductive material 340₁) and an adjacent level of dielectric material 341 (e.g., dielectric material 341 between conductive materials 340₀ and 340₁). As shown in FIG. 3C, the tiers (e.g., on levels 362, 364, 366, 368, 372, 374, 376, 378, 380, 382, and 384) can be located (e.g., stacked) one over another in the Z-direction over substrate 399. Each tier can have respective memory cells 202 (which are located on the same level (same tier) with respect to the Z-direction). Each tier can have a respective control gate (e.g., a respective word line) for memory cells 202 of the respective tier. The control gate in a tier is formed by a respective level of conductive material among conductive materials 340₀-340_{M}. FIG. 3C shows a few tiers of memory device 200 for simplicity. However, memory device 200 can include up to (or more than) one hundred tiers.

Other blocks (e.g., blocks 290 and 292 in FIG. 3B) of memory device 200 can also have their own tiers of memory cells 202 and respective control gates (e.g., respective word lines) for the memory cells, and staircase structures similar to staircase structure 333 in block 291 in FIG. 3C. For simplicity, details of staircase structures of the other blocks of memory device 200 are omitted from the description herein.

As shown in FIG. 3C, memory device 200 can include a substrate 399 and materials 396 and 397 located over (e.g., formed over) substrate 399. Substrate 399 can include semiconductor (e.g., silicon) substrate. Substrate 399 can also include circuitry 395 located under other components of memory device 200 that are formed over substrate 399. Circuitry 395 can include circuit elements (e.g., transistors Tr1 and Tr2 shown in FIG. 3C) coupled to circuit elements outside substrate 399. For example, the circuit elements outside substrate 399 can include data lines 270₀ through 270_{N} (shown in FIG. 3A) conductive contacts 365_{SGS}, 365₀-365_{M}, 365_{SGD0}, and 365_{SGD}, (FIG. 3B), part of conductive paths 391 and other (not shown) conductive connections, and other circuit elements of memory device 200. The circuit elements (e.g., transistors Tr1 and Tr2) of circuitry 395 can be configured to perform part of a function of memory device 200. For example, transistors Tr1 and Tr2 can form or can be part of decoder circuits, driver circuits (e.g., drivers 140 in FIG. 1), buffers, sense amplifiers, charge pumps, and other circuitry of memory device 200.

As shown in FIG. 3C, pillar (memory cell pillar) 330 can include a structure 335 extending along the length (in the Z-direction) of pillar 330 and coupled to a respective data line (e.g., data line 270_{N-1} or 270_{N}) and the source (which includes materials 396 and 397) of memory device 200. Structure 335 can include a conductive channel portion that can be part of a conductive path between a respective data line (e.g., data line 270_{N}) and the source (e.g., includes materials 396 and 397) to carry current (e.g., current between data line 270_{N} and materials 396 and 397) during an operation (e.g., read, write, or erase) of memory device 200.

Structure 335 of pillar 330 can include multiple layers of different materials that can be part of a TANOS (TaN, Al₂O₃, Si₃N₄, SiO₂, Si) structure of pillar 330 or a structure similar to a TANOS structure. For example, structure 335 can include a dielectric portion (e.g., interpoly dielectric portion). The dielectric portion can include a charge blocking material or materials (e.g., a dielectric material including TaN and Al₂O₃) that are capable of blocking a tunneling of a charge. Structure (e.g., TANOS structure) 335 can include a charge storage portion. The charge storage portion can include a charge storage element (e.g., charge storage material or materials, e.g., Si₃N₄) that can provide a charge storage function (e.g., trap charge) to represent a value of information stored in a respective memory cell 202. Structure (e.g., TANOS structure) 335 can include another dielectric portion (where the charge storage portion can be between the dielectric portions) that can include a tunnel dielectric material or materials (e.g., SiO₂). The tunnel dielectric material (or materials) is capable of allowing tunneling of a charge (e.g., electrons). In an alternative structure of memory device 200, structure 335 of pillar 330 can include or can be part of a SONOS (Si, SiO₂, Si₃N₄, SiO₂, Si) structure. In another alternative structure of memory device 200, structure 335 of pillar 330 can include or can be part of a floating gate structure. For example, structure 335 can include a charge storage portion that can include polysilicon (or other material) that can be part of a floating gate of a respective memory cell 202.

As shown in FIG. 3C, conductive paths (e.g., conductive routings) 391 of memory device 200 can include portions extending in the Z-direction (e.g., extending vertically). Conductive paths 391 can include (e.g., can be coupled to) some of the conductive contacts (e.g., conductive contacts 365_{SGS}, 365₁-365_{M}, and 365_{SGD0}-365_{SGDi} in FIG. 3B) or all of the conductive contacts of memory device 200. As shown in FIG. 3C, conductive paths 391 can be coupled to circuitry 395. For example, at least one of conductive paths 391 can be coupled to at least one of transistors Tr1 and Tr2 of circuitry 395.

Conductive paths 391 can provide electrical connections between elements of memory device 200. For example, conductive paths 391 can be coupled to conductive contacts 365_{SGS}, 365₀-365_{M-1}, and 365_{SGD0}-365_{SGDi} and circuit elements (e.g., word line drivers and word line decoders, not shown) of circuitry 395 to provide electrical connections (e.g., in the form of signals SGS, WL₀ through WL_{M}, and SGD₀ through SGDᵢ) from circuit elements (e.g., word line drivers, word line decoders, and charge pumps, not shown) in circuitry 395 to conductive contacts 365_{SGS}, 365₀-365_{M}, and 365_{SGD0}-365_{SGDi}, respectively.

As shown in FIG. 3C, conductive contacts 365_{SGS} and 365₀-365_{M} can include pillars (e.g., conductive pillars) 365P and 365P′. Conductive contacts 365_{SGS} and 365₀-365_{M} can have unequal lengths (different lengths) extending in the Z-direction (e.g., extending vertically (e.g., outward) from substrate 399), such that pillars 365P and 365P′ have unequal lengths. For example, pillars 365P have unequal lengths among each other. Pillars 365P′ have unequal lengths among each other. Each of pillars 365P′ can have a length that is unequal to the length of each of pillars 365P.

As shown in FIG. 3C, because of the structure (e.g., the difference in elevation of the steps) of staircase structure 333, the lengths of pillars 365P′ and 365P can be gradually increased from one pillar to the next. For example, lengths of pillars 365P′ and 365P can be gradually increased in a direction from pillar 365P′ of conductive contact 365_{M} to pillar 365P of conductive contact 365₀. Staircase structure 333 can be structured such that the length of a pillar can be less than one half of the length of another pillar. For example, the length of pillar 365P′ of conductive contacts 365_{M} can be less than one-half (½) of the length pillar 365P of conductive contacts 365₀.

As shown in FIG. 3C, each of conductive contacts 365_{SGS} and 365₀-365_{M} (including a respective pillar) can contact (e.g., land on) a respective level of a particular conductive material (among conductive materials 340_{SGS}, 340₀-340_{M}) at the location of staircase structure 333. Each conductive contact 365_{SGS} and 365₀-365_{M} can form an electrical contact with a respective conductive material (among conductive materials 340_{SGS}, 340₀-340_{M}). Thus, conductive contacts 365_{SGS}, 365₀-365_{M} (and 365_{SGD0}-365_{SGDi} shown in FIG. 3B) can be part of conductive paths (e.g., part of conductive paths 391) to carry electrical signals to the select gate (e.g., source select gate associated with signal SGS), the control gates (e.g., control gates associated with signals WL₀-WL_{M}) and other select gates (e.g., drain select gates associated with signals SGD₀-SGDᵢ), respectively.

As shown in FIG. 3C, conductive contact 365_{SGS} is electrically in contact with conductive materials 340_{SGS} and electrically separated from the rest of conductive materials (e.g., conductive materials 340₀-340_{M} and 340_{SGD0}-340_{SGDi}). Conductive contact 365₀ is electrically in contact with conductive materials 340₀ and electrically separated from the rest of conductive materials (e.g., conductive materials 340_{SGS}, 340₁, 340_{M-1}, 340_{M}, and 340_{SGDi}). Thus, a conductive contact (e.g., conductive contact 365₀) can be electrically in contact with only one of the conductive materials among the conductive materials (e.g., conductive materials 340_{SGS}, 340₀-340_{M}, and 340_{SGD0}-340_{SGDi} in FIG. 3C) of memory device 200.

As mentioned above, memory device 200 can include numerous tiers (e.g., a hundred tiers or more) in the Z-direction. Thus, the structure of some of the conductive contacts (e.g., conductive contacts 365₀ through 365₂ (deep conductive contacts)) can have a relatively high aspect ratio. Formation of such high aspect ratio conductive contacts and other structures of other conductive contacts (e.g., shallow conductive contacts (e.g., conductive contacts 365_{M-5} through 365_{M}) can be a challenge. As described in more detail below with reference to FIG. 4 through FIG. 15, improved processes (e.g., methods) can be used to mitigate or reduce defects or other limitations associated with forming conductive contacts in a memory device (e.g., memory device 200.

Materials 396 and 397 (FIG. 3C) can be part of source (e.g., a source line, a source plate, or a source region) 298 (FIG. 2) of memory device 200. Materials 396 and 397 can include different conductive materials. An example of material 396 includes tungsten silicide. An example of material 397 includes polysilicon. Materials 396 and 397 can include other conductive materials. Material 397 can include multiple levels (e.g., layers) of materials in the Z-direction. For example, material 397 can include levels (e.g., layers) of polysilicon interleaved with levels (e.g., layers) of oxide (e.g., silicon dioxide). Materials 396 and 397 can be used to form electrical connections will pillars 330 and with other electrical connections (e.g., lateral connections, not shown, in the X-direction or the Y-direction) between elements of memory device 200 in circuitry 395. A portion labeled “3D” in FIG. 3C is shown in FIG. 3D.

FIG. 3D shows detail of a portion (e.g., a side view (a cross-section perpendicular to the X-Y plan)) of part of a conductive contact 365₂ including pillar 365P. FIG. 3E shows a top view (e.g., a cross-section parallel to the X-Y plane) along line 3E-3E of FIG. 3D. The following description refers to FIG. 3D and FIG. 3E.

As shown in FIG. 3D and FIG. 3E, part of pillar 365P can be formed in an opening (e.g., hole) 365H in a dielectric material 731. For simplicity, dielectric material 731 is not shown in FIG. 3C. Pillar 365P (FIG. 3D and FIG. 3E) can include a conductive material 1433, which can include a metal material (e.g., tungsten), an alloy, or combination of metal and alloy, or other conductive materials.

As shown in FIG. 3E, conductive material 1433 can be surrounded by dielectric material 731, such that conductive material 1433 can directly contact dielectric material 731. However, in an alternative structure, memory device 200 may include a liner (e.g., dielectric liner) between conductive material 1433 and dielectric material 731.

As shown in FIG. 3D and FIG. 3E, conductive contact 365₂ can include a portion (e.g., top portion) 365T joining (coupled to) a portion (e.g., bottom portion) 365B. With respect to FIG. 3C, portion 365B is between portion 365T and a portion of the control gate (FIG. 3C) formed by conductive material 340₂. As shown in FIG. 3D, portion 365T can have a sidewall 365T_{S1} and a sidewall 365T_{S2} opposite (e.g., in the Y-direction) sidewall 365T_{S1}. Portion 365B can have a sidewall 365B_{S1} and a sidewall 365B_{S2} opposite (e.g., in the Y-direction) sidewall 365B_{S1}.

As shown in FIG. 3D, conductive contact 365₂ can have widths W1, W2, W3, and W4 at different regions. Width W1 can be measured from sidewall 365T_{S1} to sidewall 365T_{S2} of a region 365T₁ of portion 365T. Width W2 can be measured from sidewall 365B_{S1} to sidewall 365B_{S2} of a region 365B₁ of portion 365B. As shown in FIG. 3D, because of the structure (e.g., formation) of conductive contact 365₂, width W2 is greater than width W1.

Width W3 can be measured from sidewall 365T_{S1} to sidewall 365T_{S2} of a region 365T₂ of portion 365T. Width W4 can be measured from sidewall 365B_{S1} to sidewall 365B_{S2} of a region 365B₂ of portion 365B. As shown in FIG. 3D, because of the structure (e.g., formation) of conductive contact 365₂, width W3 is greater than width W4.

As shown in FIG. 3D and FIG. 3E, conductive contact 365₂ can have a kink 1065K between portion 365T and portion 365B. FIG. 3D also shows an enlarged portion of conductive contact 365₂ including kink 1065K. As shown in FIG. 3D, kink 1065K is located at a region of conductive contact 365₂ where a transition from sidewall 365T_{S1} to sidewall 365B_{S1} (or from sidewall 365T_{S2} to sidewall 365B_{S2}) does not follow the same angle (e.g., angle A1). As shown in FIG. 3D, the transition from sidewall 365T_{S1} to sidewall 365B_{S1} at kink 1065K can have an angle (e.g., angle A2 or A3) that is different from angle A1.

The presence of kink 1065K in conductive contact 365₂ and in some of the other conductive contacts (e.g., conductive contacts 365_{SGS}, 365₀, and 365₁ in FIG. 3C) of memory device 200 results from improved processes (e.g., methods) of forming conductive contacts 365_{SGS} and 365₀-365_{M}, as described below with reference to FIG. 4 through FIG. 15.

As shown in FIG. 3C, some of the conductive contacts (e.g., conductive contact 365_{M-5} through 365_{M}) of memory device 200 may not have a kink like kink 1065K of conductive contact 365₂ (FIG. 3F) in their respective pillars 365P′.

FIG. 3F shows detail of a portion (e.g., a side view (a cross-section perpendicular to the X-Y plan)) of part of a conductive contact 365_{M} including pillar 365P′. FIG. 3G shows a top view (e.g., a cross-section parallel to the X-Y plane) along line 3G-3G of FIG. 3F. The following description refers to FIG. 3F and FIG. 3G.

As shown in FIG. 3F and FIG. 3G, part of pillar 365P′ can be formed in an opening (e.g., hole) 365H′ in dielectric material 731. Pillar 365P′ can include conductive material 1433. As shown in FIG. 3G, conductive material 1433 of pillar 365P′ can be surrounded by dielectric material 731, such that conductive material 1433 can directly contact dielectric material 731. However, in an alternative structure, memory device 200 may include a liner (e.g., dielectric liner) between conductive material 1433 of pillar 365P′ and dielectric material 731.

As shown in FIG. 3F and FIG. 3G, conductive contact 365_{M} can have a sidewall 365_{S1} and a sidewall 365_{S2} opposite (e.g., in the Y-direction) sidewall 365_{S1}. Unlike conductive contact 365₂ (FIG. 3D), conductive contact 365_{M} does not have a kink like kink 1065K of conductive contact 365₂.

As shown in FIG. 3F, conductive contact 365_{M} can have a taper shape (e.g., taper shape without a kink in the entire length in the Z-direction of conductive contact 365_{M}), such that conductive contact 365_{M} can have a width (in the Y-direction from sidewall 365_{S1} to sidewall 365_{S2}) that can gradually and continuously decrease along an entire length (in the Z-direction) of conductive contact 365_{M}. The direction of the gradual and continuous decrease in the width of conductive contact 365_{M} can be a direction from the top of pillar 365P′ to the bottom of pillar 365P′ (e.g., a direction towards substrate 399). Thus, as shown in FIG. 3F, the entire sidewall (sidewall 365_{S1} or sidewall 365_{S2}) of conductive contact 365_{M} can follow the same angle (e.g., an angle similar to angle A1) such that a kink (like kink 1065K in FIG. 3D) may not be present in conductive contact 365_{M}.

FIG. 4 through FIG. 15 show different views of structures during processes of forming memory device 200 including conductive contacts 365_{SGS}, 365₀ through 365_{M} of FIG. 2 through FIG. 3E, according to some embodiments described herein. The locations of the structure of memory device 200 in FIG. 4 through FIG. 15 can correspond to the location along line 4-4 of FIG. 3A.

FIG. 4 shows memory device 200 after materials 396 and 397 are formed over substrate 399 and over circuitry 395. FIG. 4 also shows dielectric materials 341 and conductive materials 340 formed over (e.g., formed on) materials 396 and 397 and over substrate 399. Dielectric materials 341 and conductive materials 340 can be formed such that dielectric materials 341 and conductive materials 340 are interleaved with each other on respective levels (e.g., tiers) in the Z-direction. Dielectric materials 341 are the same as dielectric materials (e.g., silicon dioxide) 341 described above with reference to FIG. 3C. In FIG. 4, conductive materials 340 collectively correspond to conductive materials 340_{SGS}, 340₀ through 340_{M}, and 340_{SGD0} through 340_{SGDi} (FIG. 3C) on respective levels 362, 364, 366, 368, 372, 374, 376, 378, 380, and 382. Thus, the processes associated with FIG. 4 can include forming control gates (e.g., forming conductive materials 340) for memory cells 202 (FIG. 3C) of memory device 200 in which the control gates can be formed on tiers (corresponding to levels 362, 364, 366, 368, 372, 374, 376, 378, 380, and 382 in FIG. 4) of memory device 200.

The processes associated with FIG. 4 can include forming levels of dielectric materials (e.g., dielectric materials 341) interleaved with levels of conductive materials (e.g., conductive materials 340) over substrate 399. For simplicity, FIG. 4 omits (does not show) some of dielectric materials 341 and conductive materials 340 between levels 368 and 372. FIG. 4 also shows staircase structure 333 formed in part by respective portions and edges (e.g., edges 340E) of dielectric materials 341 and conductive materials 340.

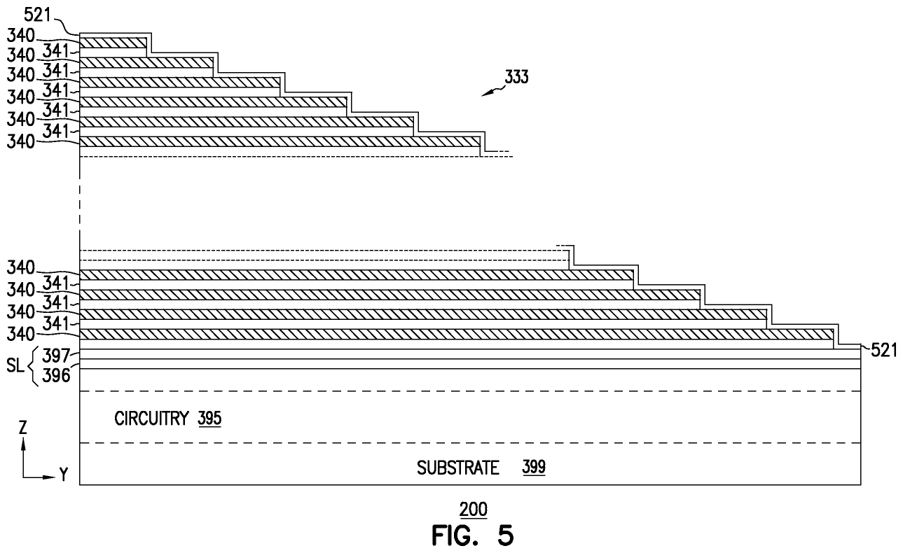

FIG. 5 shows memory device 200 after a dielectric material 521 is formed over staircase structure 333. Dielectric material 521 can include silicon dioxide. As shown in FIG. 5, dielectric material 521 can be formed such that it can be conformal to staircase structure 333 (e.g., conformal to respective portions and edges 340E of dielectric materials 341 and conductive materials 340).

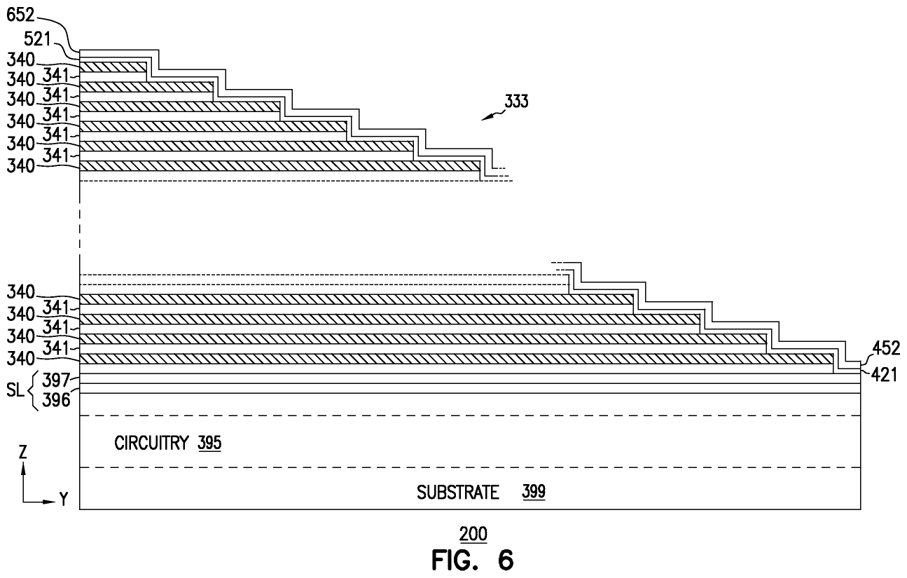

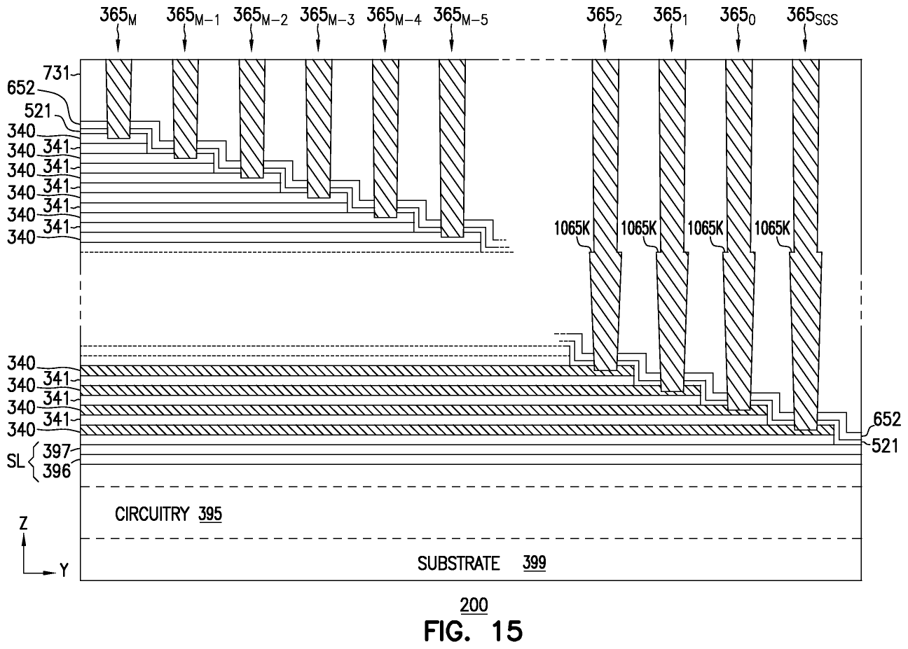

FIG. 6 shows memory device 200 after a dielectric material 652 is formed over (e.g., form on) dielectric material 521. Dielectric material 652 can include silicon nitride. As shown in FIG. 6, dielectric material 652 can be formed on dielectric material 521 such that dielectric material 652 can be conformal to dielectric material 521 at staircase structure 333. In some structures of memory device 200, dielectric materials 521 and 652 can be omitted (not formed). However, including dielectric material 652, or dielectric material 521, or both in memory device 200 can improve protection of underlying structure (e.g., conductive materials 340) from unintended removal (e.g., or alternatively from over-etching) in some of the processes of forming the conductive contacts (e.g., conductive contacts 365_{SGS}, 365₀ through 365_{M} in FIG. 3C and FIG. 15) of memory device 200.

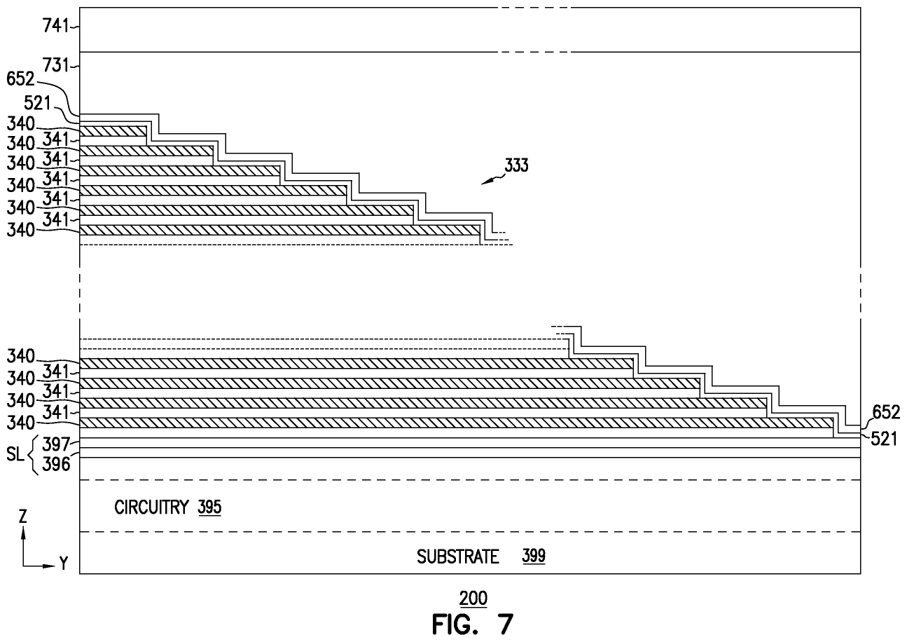

FIG. 7 shows memory device 200 after a dielectric material 731 and a material 741 are formed. Dielectric material 731 can include silicon nitride. Material 741 can include carbon or other materials. Dielectric material 731 can be formed over (e.g., formed on) dielectric material 652. Then, dielectric material 741 can be formed over (e.g., formed on) dielectric material 731. Material 741 can be used as a mask for part of forming the conductive contacts (e.g., conductive contacts 365_{SGS}, 365₀ through 365_{M} in FIG. 3C and FIG. 15) in subsequent processes. Material 741 will be subsequently removed (e.g., in FIG. 13) from memory device 200.

In subsequent processes, openings (e.g., holes) can be formed in dielectric materials 731. Part of the conductive contacts of memory device 200 can be formed in the openings formed in dielectric material 731. Part of dielectric material 731 remains in memory device 200.

The combination of dielectric materials 521, 652, and 731 (or alternatively the combination of dielectric materials 521, 652, 731, and 741) can be called a dielectric structure formed over the control gates (including staircase structure 333) of memory device 200. Thus, a portion of the dielectric structure (which includes dielectric materials 521, 652, and 731) described herein can include any combination of a portion of dielectric material 731, a portion of dielectric material 652, and portion of dielectric material 652. For example, a portion of the dielectric structure (which includes dielectric materials 521, 652, and 731) can include a portion of dielectric material 731, a portion of dielectric material 652, and portion of dielectric material 521. In another example, a portion of the dielectric structure (which includes dielectric materials 521, 652, and 731) can include a portion of dielectric material 731 (e.g., only a portion of dielectric material 731) excluding portions of dielectric materials 652 and 521. In another example, a portion of the dielectric structure (which includes dielectric materials 521, 652, and 731) can include a portion of dielectric material 652 and a portion of dielectric material 521 excluding a portion of dielectric material 731. In another example, a portion of the dielectric structure (which includes dielectric materials 521, 652, and 731) can include a portion of dielectric material 521 (e.g., only a portion of dielectric material 521) excluding portions of dielectric materials 652 and 731.

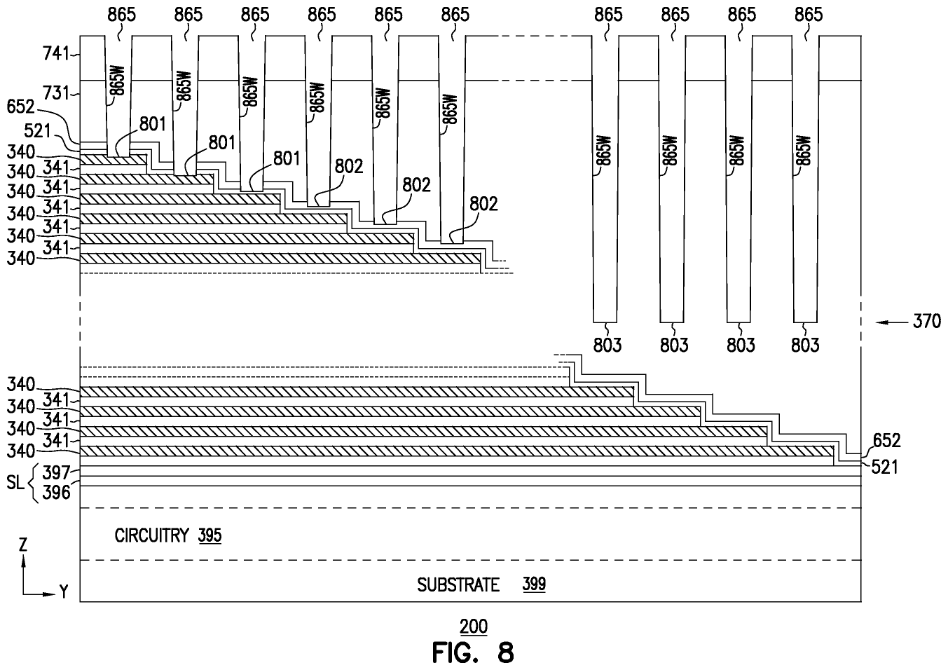

FIG. 8 shows memory device 200 after openings (e.g., holes) 865 are formed. As shown in FIG. 8, each of openings 865 can have a sidewall (e.g., vertical sidewall) 865W at respective portions of dielectric material 731 and material 741. Forming openings 865 can include removing (e.g., etching) a portion of the materials (a portion of material 741 and a portion of the dielectric structure that includes dielectric materials 731, 652, and 521) at the locations of openings 865. As shown in FIG. 8, each of openings 865 can have a depth in the Z-direction. Some of openings 865 can have the same depth and some of openings 865 can have different depths. For example, openings 865 at locations 803 can have the same depth, which corresponds to level 370 in the Z-direction. In another example, openings 865 at locations 803 can have a different depth from (e.g., greater depth than) openings 865 at locations 801 and 802. In another example, openings 865 at locations 801 (or at locations 802) can have different depths among each other.

The processes associated with FIG. 8 can be performed such that some of conductive materials 340 (e.g., at some of locations 801) may be exposed at some of openings 865 and some conductive materials 340 (e.g., at some of locations 802) are not exposed at openings 865 (e.g., are covered by a portion of the dielectric structure that include at least one of dielectric materials 652 and 521).

As described above, the processes associated with FIG. 8 can also be performed such that some of openings 865 can have respective depths (e.g., bottoms) at locations 803. Location 803 can be at level 370, which can be selected (e.g., predetermined) based on the lengths (e.g., heights) of the conductive contacts (e.g., conductive contacts 365_{SGS}, 365₀, and 365₁ in FIG. 3C) that will be formed at the locations of openings 865. For example, level 370 in FIG. 8 can be selected to be between one-half and two-third of the lengths of the conductive contacts that have longest lengths (dimension in the Z-direction) among the lengths of the conductive contacts (e.g., conductive contacts 365_{SGS} and 365₀-365_{M} in FIG. 3C or FIG. 15) of memory device 200.

Thus, the processes associated with FIG. 8 can include removing a portion of a dielectric structure (e.g., a portion of at least one of dielectric materials 521, 652, and 731 at openings 865) to form openings 865 in the dielectric structure (e.g., in a portion of at least one of dielectric materials 521, 652, and 731 at openings 865) such that a portion (a remaining portion) of the dielectric structure (e.g., a portion below locations 801, 802, and 803 in FIG. 8) is between openings 865 and the control gates (which are formed from respective materials 340 in FIG. 8).

The processes associated with FIG. 8 can also include a cleaning process after openings 865 are formed. The cleaning process can remove by product of the process (e.g., etch process) used to form openings 865.

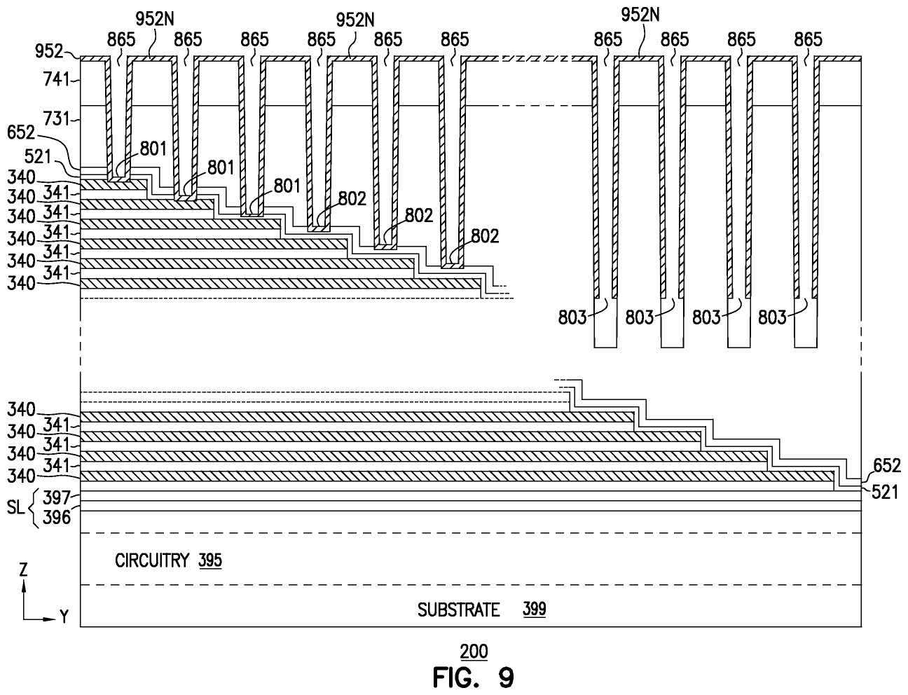

FIG. 9 shows memory device 200 after a dielectric liner 952 is formed. Dielectric liner 952 can include a material 952N. Material 952N can have an etch rate different from the etch rate of dielectric material (e.g., silicon dioxide) 521. An example for material 952N includes silicon nitride. However, material 952N can be different from silicon nitride.

Material 952N can be a relatively thin layer of material. A plasma enhanced chemical vapor deposition (PECVD) may be used to form dielectric liner 952. Dielectric liner 952 can be formed by forming (e.g., depositing) material 952N in at least a portion of each of openings 865 (e.g., formed on sidewall 865W only or formed on both sidewall 865W and the bottom of opening 865). As shown in FIG. 9, dielectric liner 952 can be formed on sidewalls 865W of openings 865 at locations 801 and 802, and on the bottom of openings 865 at locations 801 and 802. For example, at an opening 865 at location 801 or 802, vertical portions of dielectric liner 952 can be formed on sidewalls 865W and a horizontal portion of dielectric liner 952 can be formed on the bottom between the vertical portions of dielectric liner 952. Thus, material 952N can be formed over (e.g., formed on) the material (or materials) that is exposed at openings 865 (e.g., at the bottoms of openings 865) at locations 801 and 802. As shown in FIG. 9, the material exposed at openings 865 locations 801 and 802 can include respective portions of conductive materials 340, respective portions of dielectric material 521, or respective portions of dielectric material 652.

As shown in FIG. 9, dielectric liner 952 may be formed on sidewalls 865W (e.g., formed only sidewalls 865W) of openings 865 at locations 803 and not formed on the bottom of openings 865 at locations 803. For example, since openings 865 at locations 803 are formed to a greater depth than openings 865 at locations 801 and 802, material 952N of dielectric liner 952 may not be formed on (may not reach) the bottom of openings 865 at locations 803.

Thus, as shown in FIG. 9, material 952N can be conformal to sidewalls 865W and the bottoms of openings 865 at locations 801 and 802. However, material 952N may not be conformal (may be non-conformal) to the bottoms of openings 865 at locations 803. Not forming dielectric liner 952 on the bottom of openings 865 at locations 803 allows the depth of openings 865 at locations 803 to be expanded, as part of forming the conductive contacts at locations 803 (e.g., conductive contacts 365_{SGS} and 365₀ through 365₂ in FIG. 15).

Dielectric liner 952 is formed to provide improvements and benefits in the processes of forming the conductive contacts (e.g., conductive contacts 365_{SGS}, 365₀ through 365_{M} in FIG. 3C and FIG. 15) of memory device 200. Such improvements and benefits are described below after the description of FIG. 11

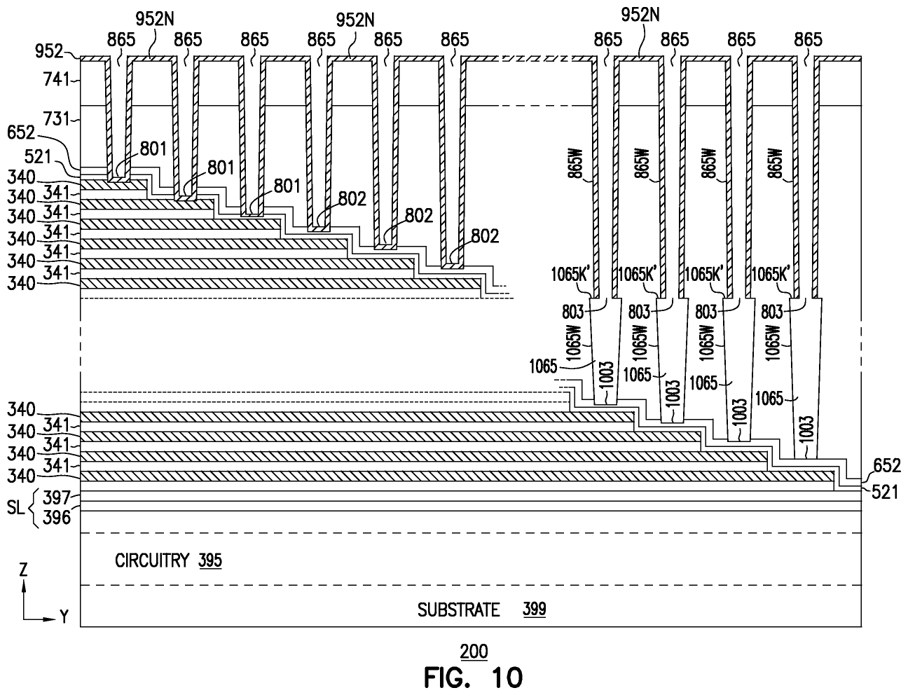

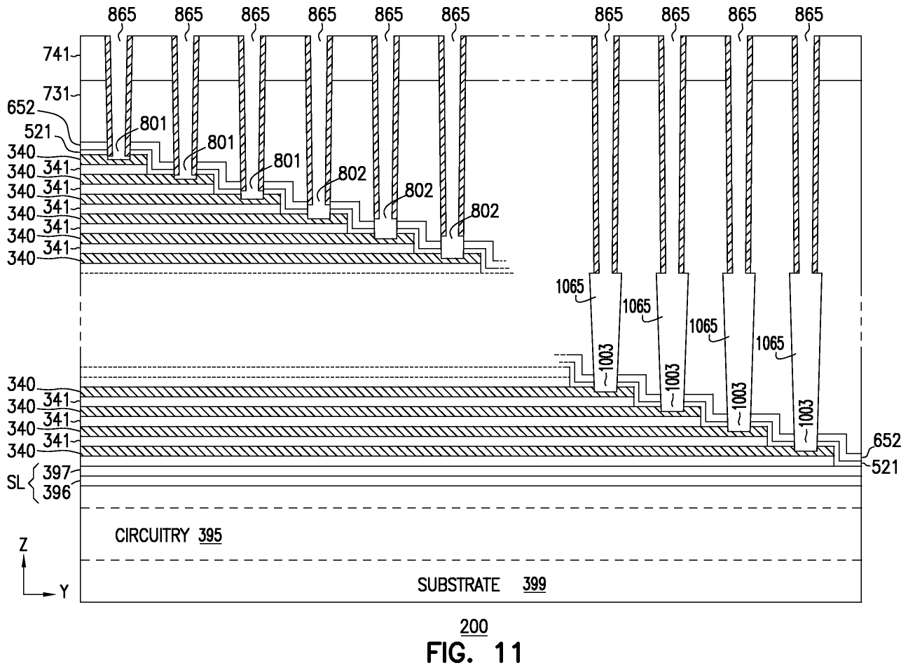

FIG. 10 shows memory device 200 after openings (holes) 1065 are formed at locations 803 (labeled in FIG. 8) at openings 865. Openings 1065 can be formed in a process (e.g., etch process) similar to that of the process of forming openings 865. Each opening 1065 can have a sidewall (e.g., vertical sidewall) 1065W. Openings 1065 are formed to extend the depths (in the Z-direction) of openings 865 from locations 803 to locations 1003.

The processes associated with FIG. 10 can be performed such that dielectric material (e.g., silicon nitride) 652 may be exposed at locations 1003. Thus, the processes associated with FIG. 10 can include performing a process (e.g., an etch process) to remove a portion of dielectric material 731 (under openings 865 at locations 803 in FIG. 9) and stopping the process (e.g., the etch process) until a portion of dielectric material 652 is exposed at the opening 865.

As shown in FIG. 10, locations 801 and 802 have the presence of material 952N of dielectric liner 952 formed over conductive material 340. Thus, material 952N can prevent an unintended removal or prevent excessive removal of conductive material 340 at locations 801 that may be caused by the process that forms openings 1065. This protection can lead to an improvement including preventing shorting or damage to the adjacent control gates

The process of forming openings 1065 may not cause openings 865 above openings 1065 to expand horizontally (e.g., to be etched laterally with respect to the Z-direction) because of the presence of material 952N. However, openings 1065 may expand horizontally (e.g., to be etched laterally with respect to the Z-direction) at locations 803 because of the absence of material 952N. Thus, as shown in FIG. 10, a kink 1065K′ can occur at a region between opening 865 and an adjacent opening 1065. Kink 1065K′ has a profile that is similar to (or the same as) the profile of kink 1065K (e.g., angles A1, A2, and A3) of conductive contact 365₂ of FIG. 3D.

FIG. 11 shows memory device 200 after a portion of dielectric material 652 and a portion of dielectric material 521 at locations 1003 are removed (e.g., etched) to expose respective portions of conductive materials 340 at locations 1003. Thus, the process associated with FIG. 10 and FIG. 11 can include removing a portion of the dielectric structure (a portion of each of dielectric materials 731, 652, and 521) between a respective opening 865 at locations 803 (FIG. 10) and a respective control gate (one of conductive materials 340 below (under) location 803) such that a portion of the respective control gate (FIG. 11) is exposed at the opening 865.

FIG. 11 also shows memory device 200 after a portion (e.g., including a bottom portion) of material 952N of dielectric liner 952 at locations 801 and 802 and respective portions of dielectric materials 652 and 531 at locations 801 and 802 (underneath dielectric liner 952 at locations 801 and 802 in FIG. 10) are removed (e.g., etched) to expose respective portions of conductive materials 340 at locations 801 and 802. A punch-through process can be used in the processes associated with FIG. 11.

As shown in FIG. 11, material 952N of the top portion of dielectric liner 952 may also be removed. Material 952N on sidewalls 865W (labeled in FIG. 8) of openings 865 may also be partially removed (e.g., may become thinner) during the processes associated with FIG. 11.

As mentioned above, dielectric liner 952 (formed in FIG. 9) provides improvements and benefits in the processes of forming the conductive contacts (e.g., conductive contacts 365_{SGS}, 365₀ through 365_{M} in FIG. 3C and FIG. 15) of memory device 200. As shown in FIG. 9, some particular openings 865 (e.g., shallow openings 865 at some of locations 801 near the top of staircase structure 333) can expose respective portions of conductive materials 340 at those particular openings 865 because dielectric materials 652 and 521 at those particular openings 865 may also be removed (e.g., etched) when openings 865 at locations 801 are formed. Such exposed portions of conductive materials 340 at locations 801 (and adjacent underlying dielectric material 341) are prone to be removed (e.g., unintentionally etched) during part of subsequent processes of forming openings for high aspect ratio conductive contacts if dielectric liner 952 (FIG. 9) is not formed (in the absence of dielectric liner 952). For example, without dielectric liner 952, the exposed portions of conductive materials 340 (and adjacent underlying dielectric material 341) at locations 801 in FIG. 8 may be removed (e.g., etch away) by one of both of the process (e.g., etch process in FIG. 10) of forming openings 1065 and the process (e.g., punch through process in FIG. 11) of removing dielectric material (e.g., silicon nitride) 652 and dielectric material (e.g., silicon dioxide) 521. Such a removal (e.g., unintended removal) can create a short (electrical short) between adjacent control gates when conductive contacts (e.g., conductive contacts 365_{M-1}, and 365_{M} in FIG. 15) are formed in the particular openings 865 at locations 801. The short causes the device memory to be defective. In some situations, a short may not be created (in the absence of dielectric liner 952). However, other damage may occur that may create a current leakage path from the control gates. This can cause the memory device to be unreliable.

As shown in FIG. 9, since dielectric liner 952 is formed (in FIG. 9), it can act as a shield to prevent the underlying conductive materials 340 (and adjacent underlying dielectric material 341) from unintended removal by one or both of the processes associated with FIG. 10 and FIG. 11. This can prevent a short between adjacent control gates or other damage.

The above discussion uses some openings 865 at locations 801 as an example. However, dielectric liner 952 can also provide similar improvements and benefits to the control gates and conductive contacts formed at openings 865 at locations 802 and 803.

Dielectric liner 952 can also reduce potential bowing (e.g., bowing at sidewalls 865W) in openings 865. This can prevent potential damage (e.g., clipping) of structures (e.g., other vertical conductive pillars, not shown) adjacent the conductive contacts (e.g., conductive contacts 365_{SGS}, 365₀ through 365_{M} in FIG. 3C and FIG. 15) formed at openings 865.

Further, staircase structure 333 may be formed such that dielectric material (e.g., silicon nitride) 652 may be limited to a certain thickness at some locations (not shown) of staircase structure 333. However, the presence of dielectric liner 952 (which can be formed from silicon nitride (e.g., material 952N in FIG. 9) can compensate such thickness limitation of dielectric material 652 and improve the structure and function of dielectric material 652.

Moreover, dielectric liner 952 can also remove the tier thickness (in the Z-direction) limitation from the tiers (which includes respective control gate) of memory device 200. For example, in some structures of memory device 200, each tier may be limited to a certain thickness (e.g., to prevent tier collapse or a short between tiers) depending on the material that forms the control gates of the tiers. However, the improvements and benefits of dielectric liner 952 described above can also remove or relax the tier thickness limitation for certain material used to form the control gates. This can allow memory device 200 to be formed with a relatively reduced (e.g., thinner) tier thickness. This in turn increases the number of tiers for a particular device area, thereby increasing memory density of memory device 200.

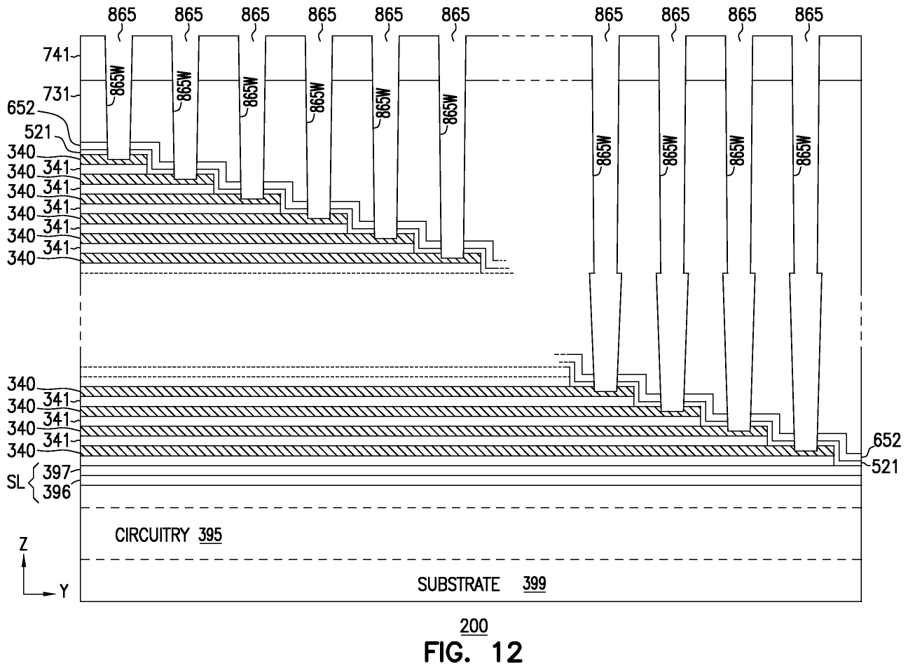

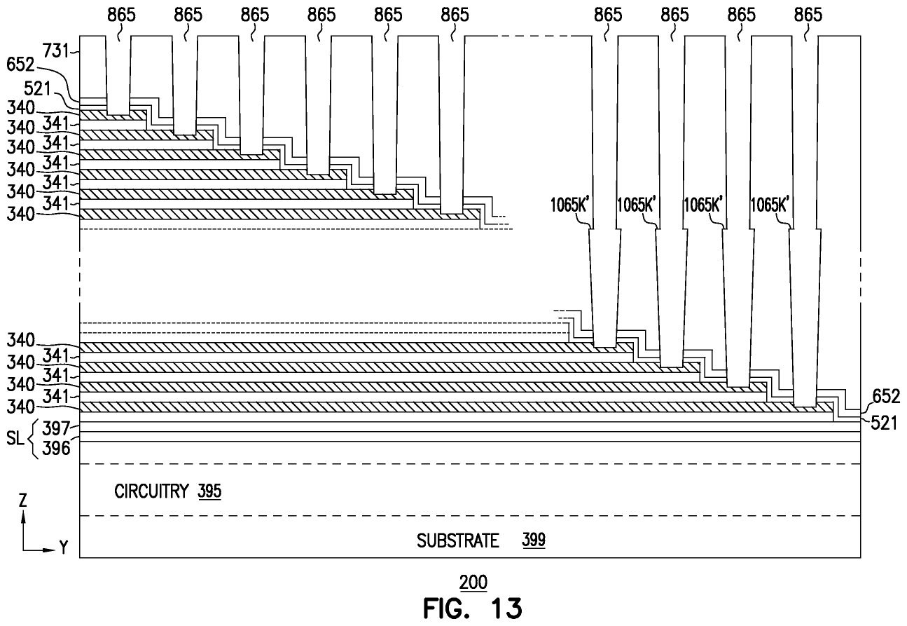

FIG. 12 shows memory device 200 after the rest of material 952N of dielectric liner 952 is removed (removed from sidewalls 865W) from openings 865. A process with a relatively good selectivity to dielectric material (e.g., silicon dioxide) 521 and conductive material 340 can be used to remove material 952N.

FIG. 13 shows memory device 200 after material (e.g., mask) 741 is removed from memory device 200. The processes associated with FIG. 13 can also include a cleaning process to remove by-product of the process associated with FIG. 13. As shown in FIG. 13, some of openings 865 have kink 1065K′ as a result of the processes of forming openings 1065 described above.

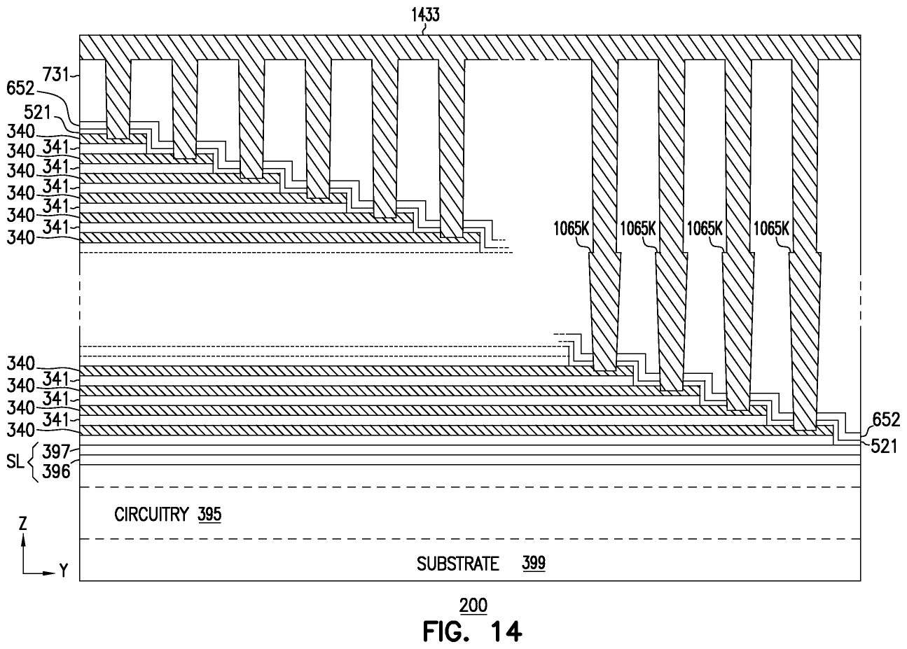

FIG. 14 shows memory device 200 after conductive material (or materials) 1433 is formed (filling) openings 865. Conductive material 1433 can be also formed on dielectric material 921. As described above with reference to FIG. 3D, conductive material 1433 can include a metal material (e.g., tungsten), an alloy, or combination of metal and alloy, or other conductive materials. As shown in FIG. 13, conductive material 1433 in some of openings 865 have kink 1065K because some of openings 1065 (FIG. 10) have kink 1065K′ that resulted from the processes of forming openings 1065 described above. Kink 1065K in FIG. 13 is the same as kink 1065K shown and described above with reference to FIG. 3D.

FIG. 15 shows memory device 200 after a portion (e.g., top portion) of conductive material 1433 is removed. For example, a chemical mechanical polishing or planarization (CMP) process can be used to remove a portion (e.g., top portion) of material 1433. A remaining portion (e.g., after a CMP process) of material 1433 is shown in FIG. 15.

As shown in FIG. 15, conductive contacts 365_{SGS}, 365₀, 365₁, 365₂, 365_{M-5}, 365_{M-4}, 365_{M-3}, 365_{M-2}, 365_{M-1}, and 365_{M} are formed. Each of these conductive contacts has a structure and materials described above with reference to FIG. 2 through FIG. 3G. Thus, for simplicity, the description in FIG. 15 omits detailed description of conductive contacts 365_{SGS}, and 365₀-365_{M}.

The processes (e.g., methods) described with reference to FIG. 4 through FIG. 15 may be concurrently performed to form elements (e.g., openings 865 in FIG. 8 and subsequent elements that lead to formation of conductive contacts 365_{SGS}, and 365₀-365_{M} (FIG. 15) of memory device 200. However, some of the processes described above can be performed separately (e.g., performed independently of some of other processes described above). For example, the processes of forming openings 865 at locations 801 and some of the subsequent processes to form corresponding conductive contacts (e.g., shallow conductive contact) at locations 801 can be formed separately. In another example, the processes of forming openings 865 at locations 802 and some of the subsequent processes to form corresponding conductive contacts (e.g., middle conductive contact) at locations 803 can be formed separately. In another example, the processes of forming openings 865 at locations 803 (and 1003) and some of the subsequent processes to form corresponding conductive contacts (e.g., deep conductive contacts) at locations 1003 can be formed separately.

The process of forming memory device 200 as described above with reference to FIG. 4 through FIG. 15 can include additional processes after the processes associated with FIG. 15 are performed. For example, additional processes can include forming drain select gates and data lines and other elements and interconnections to complete the processes of forming memory device 200.

The illustrations of apparatuses (e.g., memory devices 100 and 200) and methods (e.g., methods of forming memory device 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100 and 200) or a system (e.g., an electronic item that can include any of memory devices 100 and 200).

Any of the components described above with reference to FIG. 1 through FIG. 15 can be implemented in a number of ways, including simulation via software. Thus, apparatuses (e.g., memory devices 100 and 200), or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100 and 200) described herein may be included in apparatuses (e.g., electronic circuitry) such as high-speed computers, communication and signal processing circuitry, single- or multi processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 15 include apparatuses and methods of forming the apparatuses. One of the apparatuses includes memory cells located on tiers; control gates for the memory cells and located on respective tiers; a dielectric structure over the control gates; a first conductive contact formed in the dielectric structure and contacting a first control gate, the first conductive contact having a first length; and a second conductive contact formed in the dielectric structure and contacting the second control gate, the second conductive contact having a second length unequal to the first length, wherein the second conductive contact includes a first portion and a second portion, the second portion is between the first portion and the second control gate, the first portion including a first region having a first width, the second portion including a second region having a second width, and the second width being greater than the first width. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B, and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B, and C” means A only; B only; or C only. Item A can include a single element or multiple elements. Item B can include a single element or multiple elements. Item C can include a single element or multiple elements.

In the detailed description and the claims, the terms “first,” “second,” and “third,” etc. are used merely as labels, and are not intended to impose numerical requirements on their objects.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
memory cells located on tiers of the apparatus;
control gates for the memory cells, the control gates including a first control gate located on a first tier of the tiers, and a second control gate located on a second tier of the tiers;
a dielectric structure over the control gates;
a first conductive contact formed in the dielectric structure and contacting the first control gate, the first conductive contact having a first length in a direction from the first tier to the second tier; and
a second conductive contact formed in the dielectric structure and contacting the second control gate, the second conductive contact having a second length in the direction from the first tier to the second tier, the second length being unequal to the first length, wherein:
the second conductive contact includes a first portion and a second portion, the second portion is between the first portion and the second control gate, the first portion including a first region having a first width, the second portion including a second region having a second width, and the second width being greater than the first width.

2. The apparatus of claim 1, wherein:
the first portion of the second conductive contact includes a third region having a third width; and
the second portion of the second conductive contact includes a fourth region having a fourth width, wherein the third width is greater than the fourth width.

3. The apparatus of claim 1, wherein the dielectric structure includes:
a first dielectric material over the control gates;
a second dielectric material over the first dielectric material; and
a third dielectric material over the second dielectric material, wherein each of the first and second conductive contacts go through the first, second, and third dielectric materials.

4. The apparatus of claim 3, wherein the first dielectric material includes silicon dioxide.

5. The apparatus of claim 3, wherein the second dielectric material includes silicon nitride.

6. The apparatus of claim 3, wherein the third dielectric material includes silicon dioxide.

7. An apparatus comprising:
memory cells located on tiers of the apparatus;
control gates for the memory cells, the control gates including respective portions that form a staircase structure, the control gates including a first control gate located on a first tier of the tiers, and a second control gate located on a second tier of tiers, the first control gate including a first portion, the second control gate including a second portion, the first and second portions being part of the portions that forms the staircase structure;
a first dielectric material over the staircase structure;
a second dielectric material over the first dielectric material;
a third dielectric material over the second dielectric material;
a first conductive contact going through the first, second, and third dielectric materials and contacting the first portion of the first control gate, the first conductive contact having a first length in a direction from the first tier to the second tier; and
a second conductive contact going through the first, second, and third dielectric materials and contacting the second portion of the second control gate, the second conductive contact having a second length in the direction from the first tier to the second tier, the second length being unequal to the first length, wherein:
the second conductive contact includes a first conductive portion and a second conductive portion, the second conductive portion is between the first conductive portion and the second portion of the second control gate, the first conductive portion including a first region having a first width, the second conductive portion including a second region having a second width, wherein the second width is greater than the first width.

8. The apparatus of claim 7, wherein:
the first conductive portion of the second conductive contact includes a third region having a third width; and
the second conductive portion of the second conductive contact includes a fourth region having a fourth width, wherein the third width is greater than the fourth width.

9. The apparatus of claim 7, wherein each of the first and second conductive contacts includes a conductive material contacting the third dielectric material.

10. The apparatus of claim 7, wherein the second dielectric material includes silicon nitride.

11. The apparatus of claim 10, wherein the first dielectric material includes silicon dioxide.

12. The apparatus of claim 11, wherein the third first dielectric material includes silicon dioxide.

13. A method comprising:
forming control gates for memory cells of a memory device, the control gates formed on tiers of the memory device;
forming a dielectric structure over a staircase structure;
removing a first portion of the dielectric structure to form an opening in the dielectric structure such that a second portion of the dielectric structure is between the opening and a control gate among the control gates;
forming a dielectric liner on at least a portion of the opening;
removing the second portion of the dielectric structure such that a portion of a control gate among the control gates is exposed at the opening;
removing the dielectric liner; and
forming a conductive material in the opening and over the portion of the control gate.

14. The method of claim 13, wherein the dielectric liner includes silicon nitride.

15. The method of claim 13, wherein forming a dielectric liner on at least a portion of the opening includes forming the dielectric liner only on a sidewall of the opening.

16. The method of claim 13, wherein forming a dielectric liner on at least a portion of the opening includes forming the dielectric liner on a sidewall of the opening and on a bottom of the opening.

17. The method of claim 13, wherein forming the dielectric structure includes:
forming a first dielectric material over the control gates;
forming a second dielectric material over the first dielectric material; and
forming a third dielectric material over the second dielectric material.

18. The method of claim 17, wherein the opening is formed in only the third dielectric material among the first, second, and third dielectric materials.

19. The method of claim 17, wherein removing the second portion of the dielectric structure such that the portion of the control gate among the control gates is exposed at the opening includes:
performing a process to remove a portion of the third dielectric material and stopping the process until a portion of the second dielectric material is exposed at the opening; and
removing a portion of the second dielectric material and a portion of the first dielectric material until the portion of the control gate is exposed at the opening.

20. A method comprising:
forming control gates for memory cells of a memory device, the control gates including respective portions that form a staircase structure;
forming a dielectric structure over the staircase structure, the dielectric structure including a first dielectric material formed over the staircase structure, a second dielectric material formed over the first dielectric material, and a third dielectric material formed over the second dielectric material;
removing a first portion of the dielectric structure to form an opening in the dielectric structure such that a second portion of the dielectric structure is between the opening and a control gate among the control gates;
forming a dielectric liner on at least a portion of the opening;
removing the second portion of the dielectric structure such that a portion of the control gate is exposed at the opening;
removing the dielectric liner; and
forming a conductive material in the opening and over the portion of the control gate.

21. The method of claim 20, wherein the dielectric liner includes silicon nitride.

22. The method of claim 20, wherein:
the first dielectric material includes silicon dioxide;
the second dielectric material includes silicon nitride; and
the third first dielectric material includes silicon dioxide.

23. The method of claim 20, wherein forming the dielectric liner on at least the portion of the opening includes forming the dielectric liner only on a sidewall of the opening.

24. The method of claim 20, wherein forming the dielectric liner on at least the portion of the opening includes forming the dielectric liner on a sidewall of the opening and on a bottom of the opening.

25. A method comprising:
forming control gates for memory cells of a memory device, the control gates including respective portions that form a staircase structure;
forming a dielectric structure over the staircase structure, the dielectric structure including a first dielectric material formed over the staircase structure, a second dielectric material formed over the first dielectric material, and a third dielectric material formed over the second dielectric material;
forming a first opening in the first dielectric material and in at least a portion of one of the first and second the dielectric materials;
forming a second opening in only the third dielectric material among the first, second, and third dielectric materials;
forming a first dielectric liner on at least a portion of the first opening;
forming a second dielectric liner on at least a portion of the second opening;
removing a portion of the dielectric structure under the first opening such that a portion of a first control gate among the control gates is exposed at the first opening;
removing a portion of the dielectric structure under the second opening such that a portion of a second control gate among the control gates is exposed at the first opening;
removing the first dielectric liner and the second dielectric liner;
forming a conductive material in the first opening and over the portion of the first control gate; and
forming a conductive material in the second opening and over the portion of the second control gate.

26. The method of claim 25, wherein each of the first and second dielectric liners includes silicon nitride.

27. The method of claim 25, wherein the second opening has a depth greater than the first opening.

28. The method of claim 25, wherein:
the first dielectric material includes silicon dioxide;
the second dielectric material includes silicon nitride; and
the third first dielectric material includes silicon dioxide.

29. The method of claim 25, wherein forming a dielectric liner on at least a portion of the second opening includes forming the dielectric liner only on a sidewall of the second opening.

30. The method of claim 25, wherein:
the first opening is formed in the first dielectric material and in at least a portion of one of the first and second the dielectric materials; and
the second opening is formed in only the third dielectric material among the first, second, and third dielectric materials.
